(19) United States
(12) Patent Application Publication
(10) Pub. No.: US 2025/0260928 A1
(43) Pub. Date: Aug. 14, 2025

(54) SOUND DRIVING CIRCUIT, SOUND APPARATUS INCLUDING THE SAME, AND VEHICULAR APPARATUS INCLUDING THE SOUND APPARATUS

(71) Applicant: LG Display Co., Ltd., Seoul (KR)

(72) Inventors: Taehyung KIM, Paju-si (KR); MinKyu CHOI, Paju-si (KR); HyeonSeok KIM, Paju-si (KR)

(73) Assignee: LG Display Co., Ltd., Seoul (KR)

(21) Appl. No.: 19/044,097

(22) Filed: Feb. 3, 2025

(30) Foreign Application Priority Data
Feb. 8, 2024 (KR) 10-2024-0019611

(51) Int. Cl. H04R 3/08; H03F 3/183; H04R 1/02; H04R 1/28; H04R 9/06; H04R 17/00

(52) U.S. Cl. CPC H04R 3/08; H04R 1/025; H04R 1/2834; H04R 9/06; H04R 17/00; H03F 3/183; H03F 2200/03; H04R 2430/01; H04R 2499/13

(57) ABSTRACT

The present disclosure provides a sound driving circuit, a sound apparatus including the same, and a vehicular apparatus including the sound apparatus. The sound driving circuit includes an audio processor generating an input audio signal based on a sound source, a signal conversion circuit converting the input audio signal into a piezoelectric audio signal and an amplifier circuit amplifying the piezoelectric audio signal to generate a piezoelectric driving signal for driving a vibration apparatus of a piezoelectric-type.

### CROSS-REFERENCE TO RELATED APPLICATIONS

This application claims the benefit of and priority to Korean Patent Application No. 10-2024-0019611 filed on Feb. 8, 2024, the entirety of which is hereby incorporated by reference for all purposes as if fully set forth herein.

### BACKGROUND

### Technical Field

The present disclosure relates to a sound driving circuit, a sound apparatus including the same, and a vehicular apparatus including the sound apparatus.

### Discussion of the Related Art

A speaker applied to an apparatus may be, for example, an actuator, including a magnet and a coil. However, when the actuator is applied to the apparatus, a thickness thereof is large. Piezoelectric elements that enable thinness to be implemented are attracting much attention.

A piezoelectric device may have a characteristic where an impedance is progressively lowered toward a high frequency region (or a high-pitched sound band), and due to this, in a case where the piezoelectric device is configured with a sound driving circuit of a speaker, problems such as an overcurrent, a clipping phenomenon, and a reduction in sound quality may occur.

### SUMMARY

The inventors of present disclosure have recognized that a piezoelectric device may be driven when a power resistor is configured in a conventional sound driving circuit of a speaker. However, the inventors of present disclosure have recognized a problem where the conventional sound driving circuit, to which the power resistor is added, increases in power consumption due to the power resistor, and reliability is reduced by heat which occurs in the power resistor due to an increase in power consumption. Through various research and experiments, the inventors of present disclosure have invented a sound driving circuit which may drive a piezoelectric device by using the conventional sound driving circuit of a speaker, a sound apparatus including the same, and a vehicular apparatus including the sound apparatus.

Accordingly, embodiments of the present disclosure are directed to a sound driving circuit, a sound apparatus including the same, and a vehicular apparatus including the sound apparatus that substantially obviate one or more of the problems due to limitations and disadvantages of the related art.

An aspect of the present disclosure is to provide a sound driving circuit which may drive a piezoelectric device, a sound apparatus including the same, and a vehicular apparatus including the sound apparatus.

Another aspect of the present disclosure is to provide a sound driving circuit which may drive a speaker and a piezoelectric device, a sound apparatus including the same, and a vehicular apparatus including the sound apparatus.

Another aspect of the present disclosure is to provide a vehicular apparatus which may output a virtual engine sound through a sound apparatus including a sound driving circuit capable of driving a piezoelectric device.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive steps, as embodied and broadly described herein, a sound driving circuit comprises an audio processor generating an input audio signal based on a sound source, a signal conversion circuit converting the input audio signal into a piezoelectric audio signal, and an amplifier circuit amplifying the piezoelectric audio signal to generate a piezoelectric driving signal for driving a vibration apparatus of a piezoelectric-type.

In another aspect, a sound driving circuit comprises an audio processor generating an audio signal based on a sound source, a preamplifier circuit amplifying the audio signal to generate an input audio signal, a signal conversion circuit converting the input audio signal into a piezoelectric audio signal, and an amplifier circuit amplifying the piezoelectric audio signal to generate a piezoelectric driving signal for driving a vibration apparatus of a piezoelectric-type.

In another aspect, a sound driving circuit comprises an audio processor generating a first input audio signal and one or more second input audio signals based on a sound source; a signal conversion circuit converting the first input audio signal into a piezoelectric audio signal, and an amplifier circuit amplifying the one or more second input audio signals to generate one or more actuator driving signals for driving one or more actuators of a coil-type and amplifying the piezoelectric audio signal to generate a piezoelectric driving signal for driving a vibration apparatus of a piezoelectric-type.

In another aspect, a sound driving circuit comprises an audio processor generating a first audio signal and one or more second audio signals based on a sound source; a preamplifier circuit amplifying the one or more second audio signals to generate the one or more second input audio signals and amplifying the first audio signal to generate the first input audio signal; a signal conversion circuit converting the first input audio signal into a piezoelectric audio signal; and an amplifier circuit amplifying the one or more second input audio signals to generate one or more actuator driving signals for driving one or more actuators of a coil-type and amplifying the piezoelectric audio signal to generate a piezoelectric driving signal for driving a vibration apparatus of a piezoelectric-type

In another aspect, a sound apparatus comprises a vibration apparatus including a piezoelectric material, and a driving circuit part connected to the vibration apparatus. The driving circuit part comprises a sound driving circuit applying the piezoelectric driving signal to the vibration apparatus, as previously described.

In another aspect, a sound apparatus comprises a vibration apparatus including a piezoelectric material, one or more actuators including a magnet and a coil, and a driving circuit part connected to the vibration apparatus and the one or more actuators. The driving circuit part comprises a sound driving circuit applying the piezoelectric driving signal to the vibration apparatus and applying the one or more actuator driving signals to the one or more actuators, as previously described.

In another aspect, a vehicular apparatus comprises an exterior material; an interior material covering the exterior material; and one or more sound generating apparatuses configured to output a sound in one or more of the exterior material, the interior material, and a region between the exterior material and the interior material. The one or more sound generating apparatuses comprise a sound apparatus. The sound apparatus comprises a vibration apparatus including a piezoelectric material, and a driving circuit part connected to the vibration apparatus. The driving circuit part comprises a sound driving circuit applying the piezoelectric driving signal to the vibration apparatus, as previously described.

In another aspect, a vehicular apparatus comprises an exterior material; an interior material covering the exterior material; and one or more sound generating apparatuses configured to output a sound in one or more of the exterior material, the interior material, and a region between the exterior material and the interior material. The one or more sound generating apparatuses comprise a sound apparatus. The sound apparatus comprises a vibration apparatus including a piezoelectric material, one or more actuators including a magnet and a coil, and a driving circuit part connected to the vibration apparatus and the one or more actuators. The driving circuit part comprises a sound driving circuit applying the piezoelectric driving signal to the vibration apparatus and applying the one or more actuator driving signals to the one or more actuators, as previously described.

In another aspect, a vehicular apparatus comprises a vehicle body bottom frame, and a vehicle body bottom covering the vehicle body bottom frame, and one or more virtual engine sound apparatuses mounted on the vehicle body bottom or a region between the vehicle body bottom frame and the vehicle body bottom. The one or more virtual engine sound apparatuses comprise a sound apparatus. The sound apparatus comprises a vibration apparatus including a piezoelectric material, and a driving circuit part connected to the vibration apparatus. The driving circuit part comprises a sound driving circuit applying the piezoelectric driving signal to the vibration apparatus, as previously described.

Details of other exemplary embodiments will be included in the detailed description of the disclosure and the accompanying drawings.

A sound driving circuit, a sound apparatus including the same, and a vehicular apparatus including the sound apparatus, according to one or more embodiments of the present disclosure, may output a sound based on a vibration (or displacement) of a piezoelectric device and may prevent an overcurrent phenomenon and a clipping phenomenon occurring in a high-pitched sound band (or a high frequency region) when the piezoelectric device is vibrating (or displace).

A sound driving circuit, a sound apparatus including the same, and a vehicular apparatus including the sound apparatus, according to one or more embodiments of the present disclosure, may drive a speaker and a piezoelectric device.

A vehicular apparatus according to one or more embodiments of the present disclosure may output a virtual engine sound through a sound apparatus including a sound driving circuit capable of driving a piezoelectric device.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 illustrates a sound apparatus according to an embodiment of the present disclosure.

FIG. 2 illustrates a signal conversion circuit illustrated in FIG. 1 according to an embodiment of the present disclosure.

FIG. 3 illustrates a sound apparatus according to another embodiment of the present disclosure.

FIG. 4 illustrates a sound apparatus according to another embodiment of the present disclosure.

FIG. 5 illustrates a sound apparatus according to another embodiment of the present disclosure.

FIG. 6 illustrates a sound apparatus according to another embodiment of the present disclosure.

FIG. 7 is a cross-sectional view taken along line I-I′ illustrated in FIG. 6 according to an embodiment of the present disclosure.

FIG. 8 is an exploded perspective view illustrating the sound apparatus illustrated in FIG. 6 according to another embodiment of the present disclosure.

FIG. 9 is a cross-sectional view illustrating an apparatus according to an embodiment of the present disclosure.

FIG. 10 is a cross-sectional view illustrating a vehicular apparatus according to an embodiment of the present disclosure.

FIG. 11 is a perspective view illustrating a vehicular apparatus according to another embodiment of the present disclosure.

FIG. 12 is a cross-sectional view taken along line II-II′ illustrated in FIG. 11 according to an embodiment of the present disclosure.

FIG. 13 is a perspective view illustrating a vibration apparatus according to an embodiment of the present disclosure.

FIG. 14 is a cross-sectional view taken along line III-III′ illustrated in FIG. 13 according to an embodiment of the present disclosure.

FIG. 15 is a cross-sectional view taken along line IV-IV′ illustrated in FIG. 13 according to an embodiment of the present disclosure.

FIG. 16 is a perspective view illustrating a vibration layer according to another embodiment of the present disclosure.

FIG. 17 is a perspective view illustrating a vibration layer according to another embodiment of the present disclosure.

FIG. 18 is an exploded perspective view illustrating a vibration apparatus according to another embodiment of the present disclosure.

FIG. 19 is a plan view illustrating a vehicular apparatus according to another embodiment of the present disclosure.

FIG. 20 is a cross-sectional view taken along line V-V′ illustrated in FIG. 19 according to an embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and convenience.

### DETAILED DESCRIPTION

Advantages and features of the present disclosure, and implementation methods thereof, are clarified through the aspects described with reference to the accompanying drawings. The present disclosure may, however, be embodied in different forms and should not be construed as limited to the example aspects set forth herein. Rather, these example aspects are examples and are provided so that this disclosure may be thorough and complete to assist those skilled in the art to understand the inventive concepts without limiting the protected scope of the present disclosure.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In a situation where “comprise,” “have,” and “include” described in the present specification are used, another part may be added unless “only” is used. The terms of a singular form may include plural forms unless referred to the contrary.

In construing an element, the element is construed as including an error range although there is no explicit description.

In describing a position relationship, for example, when a position relation between two parts is described as “on,” “over,” “under,” and “next,” one or more other parts may be disposed between the two parts unless ‘just’ or ‘direct’ is used.

In describing a temporal relationship, for example, when the temporal order is described as “after,” “subsequent,” “next,” and “before,” a situation which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element is “connected,” “coupled,” or “contact,” to another element, the element may not only be directly connected, coupled, or contacted to another element, but also be indirectly connected, coupled, or contacted to another element with one or more intervening elements interposed between the elements, unless otherwise specified.

For the expression that an element is “contacts” or “overlaps” with another element, the element may not only directly contact, overlap, or the like with another element, but also indirectly contact or overlap with another element with one or more intervening elements disposed or interposed between the elements, unless otherwise specified.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art may sufficiently understand. The embodiments of the present disclosure may be carried out independently from each other or may be carried out together in co-dependent relationship.

Hereinafter, example embodiments of a sound apparatus according to the present disclosure will be described in detail with reference to the accompanying drawings. For convenience of description, a scale of each of elements illustrated in the accompanying drawings differs from a real scale, and thus, is not limited to a scale illustrated in the drawings.

FIG. 1 illustrates a sound apparatus according to an embodiment of the present disclosure.

With reference to FIG. 1, a sound apparatus according to an embodiment (or a first embodiment) of the present disclosure may include a vibration apparatus 10 and a driving circuit part 100 connected to the vibration apparatus 10.

The vibration apparatus 10 may be configured to include a piezoelectric material. The vibration apparatus 10 may vibrate (or displace) based on a piezoelectric driving signal PDS applied from the driving circuit part 100 to output (or generate) a sound (or vibration or sound wave). For example, the vibration apparatus 10 may be a piezoelectric device, a vibration generating device, a vibration film, a vibration generating film, an active vibration generator, a film actuator, or a film exciter, or the like, but embodiments of the present disclosure are not limited thereto.

The driving circuit part 100 may include a sound driving circuit 101 configured to supply the piezoelectric driving signal PDS to the vibration apparatus 10.

The sound driving circuit 101 according to an embodiment of the present disclosure may include a signal conversion circuit 120 and an amplifier circuit 130.

The signal conversion circuit 120 may be configured to convert an input audio signal (or an input audio data) IAS into a piezoelectric audio signal PAS. For example, the signal conversion circuit 120 may be configured to convert the input audio signal IAS into the piezoelectric audio signal PAS so as to correspond to a driving characteristic of the vibration apparatus 10 of a piezoelectric type (or a piezoelectric device or a piezoelectric-type vibration device). For example, the vibration apparatus 10 may have a characteristic where an impedance is progressively lowered toward a high frequency region (or a high-pitched sound band), and due to this, an overcurrent caused by a peak component occurring in the high frequency region (or high-pitched sound band), a clipping phenomenon caused by the overcurrent, and a reduction in a sound quality may occur. For example, the clipping phenomenon may occur when a signal which is greater than or equal to an allowable voltage is applied to the amplifier circuit 130.

The signal conversion circuit 120 according to an embodiment of the present disclosure may convert the input audio signal IAS into the piezoelectric audio signal PAS so that an overcurrent is prevented in a high-pitched sound band signal (or a high frequency region) of the input audio signal IAS. For example, the signal conversion circuit 120 may be configured to limit a voltage, corresponding to the input audio signal IAS, to less than an allowable voltage of the amplifier circuit 130. For example, the signal conversion circuit 120 may be configured to generate the piezoelectric audio signal PAS by attenuating the high-pitched sound band signal of the input audio signal IAS. For example, the signal conversion circuit 120 may be configured to generate the piezoelectric audio signal PAS by linearly attenuating the high-pitched sound band signal of the input audio signal IAS. For example, the high-pitched sound band signal may have a frequency of 1 kHz or more, but embodiments of the present disclosure are not limited thereto. For example, the signal conversion circuit 120 may be configured to generate the piezoelectric audio signal PAS by attenuating an attenuation frequency (or a cutoff frequency) or more of the input audio signal IAS. For example, the signal conversion circuit 120 may be configured to generate the piezoelectric audio signal PAS by attenuating a signal of the attenuation frequency or more of the input audio signal IAS. For example, the attenuation frequency may be 1 kHz, but embodiments of the present disclosure are not limited thereto.

The amplifier circuit 130 may receive the piezoelectric audio signal PAS output from the signal conversion circuit 120 and may amplify the received piezoelectric audio signal PAS to generate the piezoelectric driving signal PDS. For example, the amplifier circuit 130 may amplify the piezoelectric audio signal PAS to generate the piezoelectric driving signal PDS, based on a predetermined gain value. For example, the amplifier circuit 130 may amplify the piezoelectric audio signal PAS to generate the piezoelectric driving signal PDS having a positive polarity and a negative polarity and may supply (or transfer) the piezoelectric driving signal PDS having the positive polarity and the negative polarity to the vibration apparatus 10.

According to an embodiment of the present disclosure, the amplifier circuit 130 may receive (or apply) the piezoelectric audio signal PAS from the signal conversion circuit 120 and may amplify the piezoelectric audio signal PAS within a range of an allowable voltage to generate the piezoelectric driving signal PDS. Accordingly, a clipping phenomenon occurring based on a vibration (or displacement) of the vibration apparatus 10 may be prevented.

The sound driving circuit 101 according to an embodiment of the present disclosure may further include an audio processor 110.

The audio processor 110 may be configured to supply (or transfer) the input audio signal IAS to the signal conversion circuit 120. For example, the audio processor 110 may generate an audio signal, based on a sound source SS input based on control by a host system (or host controller), and may be configured to supply (or transfer) the generated audio signal as the input audio signal IAS to the signal conversion circuit 120.

The vibration apparatus 10 may vibrate (or displace) based on the piezoelectric driving signal PDS applied from the amplifier circuit 130 of the driving circuit part 100 (or the sound driving circuit 101) to output (or generate) the sound (or vibration or sound wave).

According to an embodiment of the present disclosure, the vibration apparatus 10 may vibrate (or displace) by the piezoelectric driving signal PDS based on the piezoelectric audio signal PAS where an overcurrent is limited by the signal conversion circuit 120 in the high-pitched sound band, and thus, an overcurrent phenomenon and a clipping phenomenon occurring in the high-pitched sound band (or high frequency region) may be prevented.

In the sound driving circuit 101 according to an embodiment of the present disclosure, the audio processor 110 and the amplifier circuit 130 may be considered as a conventional sound driving circuit of a speaker. For example, the sound driving circuit 101 according to an embodiment of the present disclosure may include the signal conversion circuit 120 connected between the audio processor 110 and the amplifier circuit 130 in the conventional sound driving circuit of the speaker. Accordingly, because the sound driving circuit 101 according to an embodiment of the present disclosure includes the signal conversion circuit 120 added to the conventional sound driving circuit of the speaker, the sound driving circuit 101 may drive (or vibrate or displace) the vibration apparatus 10 of a piezoelectric type and may prevent an overcurrent phenomenon and a clipping phenomenon from occurring in the high-pitched sound band (or high frequency region) when the vibration apparatus 10 is being driven.

In the sound driving circuit 101 according to an embodiment of the present disclosure, the audio processor 110, the signal conversion circuit 120, and the amplifier circuit 130 may be mounted on one printed circuit board (PCB). For example, in the PCB, a signal line 101L between the audio processor 110 and the amplifier circuit 130 may be disconnected or there is not a signal line between the audio processor 110 and the amplifier circuit 130. Accordingly, the input audio signal IAS output from the audio processor 110 may not be supplied to the amplifier circuit 130 (e.g., through the disconnected signal line 101L) and may be supplied to only the signal conversion circuit 120. For comparison, in the conventional sound driving circuit of the speaker, the audio processor is connected to the amplifier circuit through the signal line so that the input audio signal is transferred to the amplifier circuit without conversion.

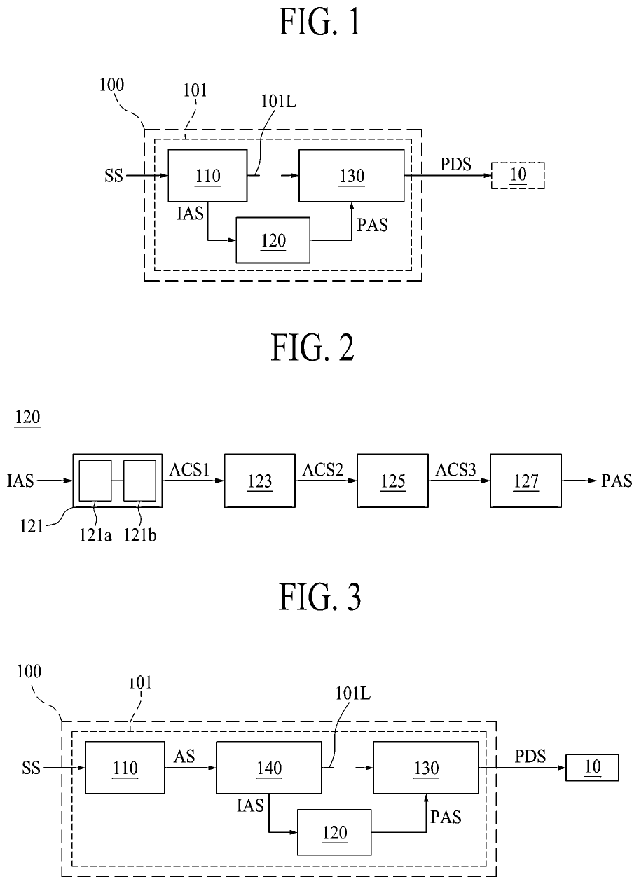

FIG. 2 illustrates a signal conversion circuit illustrated in FIG. 1 according to an embodiment of the present disclosure.

With reference to FIGS. 1 and 2, the signal conversion circuit 120 according to an embodiment of the present disclosure may include a filter circuit 127.

The filter circuit 127 may filter the input audio signal IAS to generate the piezoelectric audio signal PAS, so that an overcurrent is prevented in the high-pitched sound band signal (for example, with a frequency of 1 kHz or more) of the input audio signal IAS. For example, the filter circuit 127 may be configured to limit a voltage, corresponding to the input audio signal IAS, to less than an allowable voltage of the amplifier circuit 130, but embodiments of the present disclosure are not limited thereto.

The filter circuit 127 may be configured to generate the piezoelectric audio signal PAS by attenuating the high-pitched sound band signal of the input audio signal IAS. The filter circuit 127 may be configured to generate the piezoelectric audio signal PAS by linearly attenuating the high-pitched sound band signal of the input audio signal IAS. For example, the filter circuit 127 may be configured to generate the piezoelectric audio signal PAS by attenuating a signal of the attenuation frequency (for example, 1 kHz) or more of the input audio signal IAS. For example, the filter circuit 127 may be configured to generate the piezoelectric audio signal PAS by linearly attenuating the signal of the attenuation frequency or more of the input audio signal IAS. For example, the filter circuit 127 may be a piezo equalizer, a piezo filter, a low-pass filter, a high-cut filter, or a treble-cut filter, but embodiments of the present disclosure are not limited thereto.

The signal conversion circuit 120 according to an embodiment of the present disclosure may include a correction circuit 121, a level control circuit 123, and a clipping circuit 125.

The correction circuit 121 may correct the input audio signal IAS so that a difference between a highest sound pressure level and a lowest sound pressure level is reduced in a specific pitched sound band (or a specific frequency band) of a sound generated based on a vibration (or displacement) of the vibration apparatus 10. The correction circuit 121 may correct the input audio signal IAS to improve the sound pressure level flatness of a sound generated based on a vibration (or displacement) of the vibration apparatus 10. For example, the correction circuit 121 may correct the input audio signal IAS so that a dip component (or a dip frequency) and/or a peak component (or a peak frequency) are/is improved in a specific pitched sound band of a sound generated based on a vibration (or displacement) of the vibration apparatus 10. The peak may be a phenomenon where a sound pressure level bounces in a specific frequency, and the dip may be a phenomenon where a low sound pressure level is generated as the occurrence of a sound having a specific frequency is prevented. The flatness of the sound pressure level may be a level of the deviation between the highest sound pressure level and the lowest sound pressure level in a specific frequency. For example, the correction circuit 121 may be a planarization circuit, a tuning equalizer, or a peak/dip correction circuit, but embodiments of the present disclosure are not limited thereto.

The correction circuit 121 according to an embodiment of the present disclosure may increase a first pitched sound band signal of the input audio signal IAS and/or may decrease a second pitched sound band signal differing from the first pitched sound band signal to generate a first audio correction signal ACS1.

According to an embodiment of the present disclosure, the correction circuit 121 may correct the input audio signal IAS so that a dip phenomenon (or a dip frequency) is improved in the first pitched sound band signal of a sound generated based on a vibration (or displacement) of the vibration apparatus 10. For example, the correction circuit 121 may be configured to increase the first pitched sound band signal of the input audio signal IAS. For example, the correction circuit 121 may be configured to increase, by a predetermined value, a value (or a level) of the first pitched sound band signal of the input audio signal IAS. For example, the correction circuit 121 may increase the value (or level) of the first pitched sound band signal of the input audio signal IAS by up to a maximum of 3 decibels (+3 dB), but embodiments of the present disclosure are not limited thereto. For example, the first pitched sound band signal may have a frequency of 250 Hz to 600 Hz, but embodiments of the present disclosure are not limited thereto.

According to an embodiment of the present disclosure, the correction circuit 121 may correct the input audio signal IAS so that a peak phenomenon (or a peak frequency) is improved in the second pitched sound band signal of a sound generated based on a vibration (or displacement) of the vibration apparatus 10. For example, the correction circuit 121 may be configured to decrease the second pitched sound band signal of the input audio signal IAS. For example, the correction circuit 121 may decrease, by a predetermined value, a value (or a level) of the second pitched sound band signal of the input audio signal IAS to generate the first audio correction signal ACS1. For example, the correction circuit 121 may decrease the value (or level) of the second pitched sound band signal of the input audio signal IAS by up to a maximum of 3 decibels (−3 dB), but embodiments of the present disclosure are not limited thereto. For example, the second pitched sound band signal may have a frequency of 1 kHz or more, 4 kHz or more, or 10 kHz or more, but embodiments of the present disclosure are not limited thereto.

The correction circuit 121 according to an embodiment of the present disclosure may include a first correction circuit 121a and a second correction circuit 121b.

The first correction circuit 121a may be configured to increase the first pitched sound band signal of the input audio signal IAS. The second correction circuit 121b may decrease the second pitched sound band signal in a signal obtained by increasing the first pitched sound band through the first correction circuit 121a to generate the first audio correction signal ACS1.

The correction circuit 121 according to another embodiment of the present disclosure may include a first correction circuit 121a, a second correction circuit 121b, and a mixing circuit.

The first correction circuit 121a may be configured to increase the first pitched sound band signal of the input audio signal IAS. The second correction circuit 121b may be configured to decrease the second pitched sound band signal of the input audio signal IAS. The mixing circuit may mix the signal, obtained by increasing the first pitched sound band signal through the first correction circuit 121a, with a signal obtained by decreasing the second pitched sound band signal through the second correction circuit 121b to generate the first audio correction signal ACS1.

The first audio correction signal ACS1 output from the correction circuit 121 according to another embodiment of the present disclosure may be a signal where a dip phenomenon and a peak phenomenon have been improved in the input audio signal IAS. For example, the first audio correction signal ACS1 may be a signal where a dip phenomenon has been improved in the first pitched sound band signal of the input audio signal IAS and a peak phenomenon has been improved in the second pitched sound band signal of the input audio signal IAS.

The level control circuit 123 may be configured to control a volume (or a volume level) of the first audio correction signal ACS1 output from the correction circuit 121. The level control circuit 123 may receive the first audio correction signal ACS1 output from the correction circuit 121 and may control a volume level of the received first audio correction signal ACS1 to generate a second audio correction signal ACS2. For example, the level control circuit 123 may control one or more of a phase and an amplitude of the first audio correction signal ACS1 to generate the second audio correction signal ACS2, based on a gain value.

The clipping circuit 125 may be configured to generate a third audio correction signal ACS3 by removing noise of the second audio correction signal ACS2 output from the level control circuit 123. The clipping circuit 125 may receive the second audio correction signal ACS2 output from the level control circuit 123 and may be configured to generate the third audio correction signal ACS3 by removing noise of the received second audio correction signal ACS2. For example, the clipping circuit 125 may be configured to prevent the occurrence of a clipping phenomenon caused by an increase in frequency band based on the amplification of a signal by the amplifier circuit 130. The clipping circuit 125 according to an embodiment of the present disclosure may remove a signal of 0 dBFS (dB full scale) or more in the second audio correction signal ACS2 output from the level control circuit 123 to generate the third audio correction signal ACS3. For example, the clipping circuit 125 may be a limiter, but embodiments of the present disclosure are not limited thereto.

The filter circuit 127 may be configured to generate the piezoelectric audio signal PAS by attenuating a high-pitched sound band (or a high frequency) signal of the third audio correction signal ACS3 output from the clipping circuit 125. The filter circuit 127 may receive the third audio correction signal ACS3 output from the clipping circuit 125 and may attenuate the high-pitched sound band (or high frequency) signal of the received third audio correction signal ACS3 to generate the piezoelectric audio signal PAS.

According to an embodiment of the present disclosure, the vibration apparatus 10 may vibrate (or displace) based on the piezoelectric driving signal PDS based on the piezoelectric audio signal PAS generated by the signal conversion circuit 120 including the correction circuit 121, the level control circuit 123, the clipping circuit 125, and the filter circuit 127 to output (or generate) a sound (or vibration or sound wave), may prevent an overcurrent phenomenon and a clipping phenomenon occurring in the high-pitched sound band (or high frequency region), and may improve the dip phenomenon in the first pitched sound band and the peak phenomenon in the second pitched sound band, thereby enhancing a sound characteristic and/or a sound pressure level characteristic.

FIG. 3 illustrates a sound apparatus according to another embodiment of the present disclosure. For example, FIG. 3 illustrates an embodiment where a preamplifier circuit is additionally configured in the sound driving circuit of the sound apparatus described above with reference to FIGS. 1 and 2. In the following description, therefore, a preamplifier circuit will be described in detail, the other elements may be substantially a same as that of descriptions described above with reference to FIGS. 1 and 2, and thus, like reference numerals refer to like elements and its repeated descriptions may be omitted or will be briefly given below.

With reference to FIG. 3, in a sound apparatus according to another embodiment (or a second embodiment) of the present disclosure, the sound driving circuit 101 of the driving circuit part 100 may include a preamplifier circuit 140, a signal conversion circuit 120, and an amplifier circuit 130.

The preamplifier circuit 140 may amplify an audio signal AS input thereto to generate the input audio signal IAS. For example, the pre-amplifier circuit 140 may primarily amplify the audio signal AS to generate the input audio signal IAS, based on a predetermined gain value. The preamplifier circuit 140 may be configured to supply (or transfer) the input audio signal IAS to the signal conversion circuit 120.

The signal conversion circuit 120 may receive the input audio signal IAS output from the preamplifier circuit 140 and may be configured to convert the received input audio signal IAS into a piezoelectric audio signal PAS. Except for that the signal conversion circuit 120 receives the input audio signal IAS output from the preamplifier circuit 140, the signal conversion circuit 120 may be a same or substantially a same as the signal conversion circuit 120 described above with reference to FIGS. 1 and 2, and thus, its repeated descriptions are omitted. The descriptions of the signal conversion circuit 120 described above with reference to FIGS. 1 and 2 may be included in descriptions of the signal conversion circuit 120 illustrated in FIG. 3. The signal conversion circuit 120 may be configured to supply (or transfer) the piezoelectric audio signal PAS to the amplifier circuit 130.

The amplifier circuit 130 may amplify the piezoelectric audio signal PAS to generate a piezoelectric driving signal PDS and may be configured to apply the piezoelectric driving signal PDS to the vibration apparatus 10. For example, the amplifier circuit 130 may be a same or substantially a same as the amplifier circuit 130 described above with reference to FIGS. 1 and 2, and thus, its repeated descriptions are omitted.

The sound driving circuit 101 according to another embodiment of the present disclosure may further include an audio processor 110.

The audio processor 110 may be configured to supply (or transfer) the audio signal AS to the preamplifier circuit 140. For example, the audio processor 110 may generate the audio signal AS, based on a sound source SS input based on control by the host system (or host controller), and may be configured to supply (or transfer) the generated audio signal AS to the preamplifier circuit 140.

In the sound driving circuit 101 according to an embodiment of the present disclosure, the audio processor 110, the signal conversion circuit 120, the amplifier circuit 130, and the preamplifier circuit 140 may be mounted on one printed circuit board (PCB). For example, in the PCB, a signal line 101L between the preamplifier circuit 140 and the amplifier circuit 130 may be disconnected or there is not a signal line between the preamplifier circuit 140 and the amplifier circuit 130. Accordingly, the input audio signal IAS output from the preamplifier circuit 140 may not be supplied to the amplifier circuit 130 (e.g., through the disconnected signal line 101L) and may be supplied to only the signal conversion circuit 120.

The vibration apparatus 10 may vibrate (or displace) based on the piezoelectric driving signal PDS applied from the amplifier circuit 130 of the driving circuit part 100 (or the sound driving circuit 101) to output (or generate) the sound (or vibration or sound wave), may prevent an overcurrent phenomenon and a clipping phenomenon occurring in the high-pitched sound band (or high frequency region), and may improve the dip phenomenon in the first pitched sound band and the peak phenomenon in the second pitched sound band, thereby enhancing a sound characteristic and/or a sound pressure level characteristic.

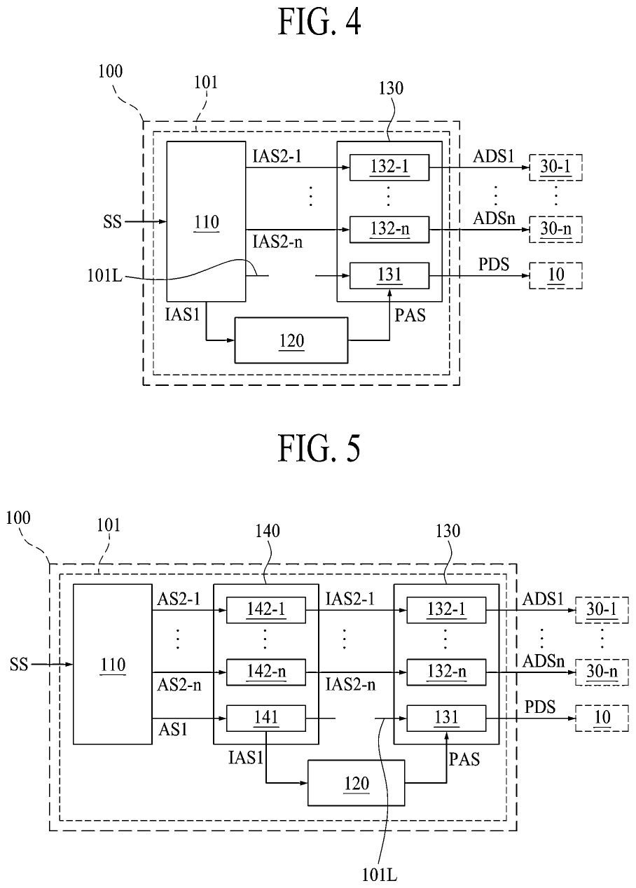

FIG. 4 illustrates a sound apparatus according to another embodiment of the present disclosure.

With reference to FIG. 4, a sound apparatus according to another embodiment (or a third embodiment) of the present disclosure may include a vibration apparatus 10, one or more (or a plurality of) actuators (or speakers) 30-1 to 30-n including a magnet and a coil (or a voice coil), and a driving circuit part 100 connected to the vibration apparatus 10 and the one or more (or plurality of) actuators 30-1 to 30-n.

The vibration apparatus (or piezoelectric device) 10 may vibrate (or displace) based on the piezoelectric driving signal PDS applied from the driving circuit part 100 to output (or generate) a sound (or vibration or sound wave).

The one or more (or plurality of) actuators 30-1 to 30-n may be a coil-type vibration apparatus or a coil-type actuator. For example, the one or more (or plurality of) actuators 30-1 to 30-n may vibrate (or be driven) based on actuator driving signals (or speaker driving signals) ADS1 to ADSn applied from the driving circuit part 100 according to Fleming's left-hand rule to output (or generate) a sound (or vibration or sound wave).

The driving circuit part 100 may include a sound driving circuit 101 configured to drive the vibration apparatus 10 and the one or more (or plurality of) actuators 30-1 to 30-n. The sound driving circuit 101 may supply the piezoelectric driving signal PDS to the vibration apparatus 10 and may supply the actuator driving signals ADS1 to ADSn to the one or more (or plurality of) actuators 30-1 to 30-n.

The sound driving circuit 101 according to another embodiment of the present disclosure may include a signal conversion circuit 120 and an amplifier circuit 130 and may further include an audio processor 110.

The audio processor 110 may be configured to generate a first input audio signal (or a first input audio data) IAS1 and one or more (or a plurality of) second input audio signals (or second input audio data) IAS2-1 to IAS2-n. For example, the audio processor 110 may generate the first audio signal and one or more (or a plurality of) second audio signals based on a sound source SS input based on control by a host system (or host controller). The audio processor 110 may be configured to supply (or transfer) the first audio signal as the first input audio signal IAS1 to the signal conversion circuit 120 and may be configured to supply (or transfer) the one or more (or plurality of) second audio signals as the one or more (or plurality of) second input audio signals IAS2-1 to IAS2-n to the amplifier circuit 130.

The audio processor 110 according to an embodiment of the present disclosure may be configured to generate the plurality of second input audio signals IAS2-1 to IAS2-n to supply (or transfer) the second input audio signals IAS2-1 to IAS2-n to the amplifier circuit 130, based on the sound source SS. For example, the plurality of second input audio signals IAS2-1 to IAS2-n may be equal to or different from one another.

The signal conversion circuit 120 may receive the first input audio signal IAS1 output from the audio processor 110 and may be configured to convert the received first input audio signal IAS1 into a piezoelectric audio signal PAS. Except for that the signal conversion circuit 120 receives the first input audio signal IAS1 output from the audio processor 110, the signal conversion circuit 120 may be a same or substantially a same as the signal conversion circuit 120 described above with reference to FIGS. 1 and 2, and thus, its repeated descriptions are omitted. The descriptions of the signal conversion circuit 120 described above with reference to FIGS. 1 and 2 may be included in descriptions of the signal conversion circuit 120 illustrated in FIG. 4. The signal conversion circuit 120 may be configured to supply (or transfer) the piezoelectric audio signal PAS to the amplifier circuit 130.

The amplifier circuit 130 may be configured to generate the one or more (or plurality of) actuator driving signals ADS1 to ADSn by amplifying the one or more (or plurality of) second input audio signals IAS2-1 to IAS2-n and may also be configured to generate the piezoelectric driving signal PDS by amplifying the piezoelectric audio signal PAS.

The amplifier circuit 130 may receive the one or more (or plurality of) second input audio signals IAS2-1 to IAS2-n output from the audio processor 110 and may amplify the received one or more (or plurality of) second input audio signals IAS2-1 to IAS2-n to generate the one or more (or plurality of) actuator driving signals ADS1 to ADSn. For example, the amplifier circuit 130 may amplify the one or more (or plurality of) second input audio signals IAS2-1 to IAS2-n to generate the one or more (or plurality of) actuator driving signals ADS1 to ADSn, based on a predetermined gain value. For example, the amplifier circuit 130 may amplify the one or more (or plurality of) second input audio signals IAS2-1 to IAS2-n to generate the one or more (or plurality of) actuator driving signals ADS1 to ADSn having a positive polarity and a negative polarity and may supply (or transfer) the one or more (or plurality of) actuator driving signals ADS1 to ADSn having the positive polarity and the negative polarity to the one or more (or plurality of) actuators 30-1 to 30-n.

The amplifier circuit 130 may receive the piezoelectric audio signal PAS output from the signal conversion circuit 120 and may amplify the received piezoelectric audio signal PAS to generate the piezoelectric driving signal PDS. For example, the amplifier circuit 130 may amplify the piezoelectric audio signal PAS to generate the piezoelectric driving signal PDS, based on a predetermined gain value. For example, the amplifier circuit 130 may amplify the piezoelectric audio signal PAS to generate the piezoelectric driving signal PDS having a positive polarity and a negative polarity and may supply (or transfer) the piezoelectric driving signal PDS having the positive polarity and the negative polarity to the vibration apparatus 10.

According to an embodiment of the present disclosure, the amplifier circuit 130 may receive (or apply) the piezoelectric audio signal PAS from the signal conversion circuit 120 and may amplify the piezoelectric audio signal PAS within a range of an allowable voltage to generate the piezoelectric driving signal PDS. Accordingly, a clipping phenomenon occurring based on a vibration (or displacement) of the vibration apparatus 10 may be prevented.

The amplifier circuit 130 according to an embodiment of the present disclosure may include a first amplifier circuit 131 and one or more (or a plurality of) second amplifier circuits 132-1 to 132-n.

The first amplifier circuit 131 may generate the piezoelectric driving signal PDS by amplifying the piezoelectric audio signal PAS output from the signal conversion circuit 120, based on a predetermined gain value. For example, the first amplifier circuit 131 may generate the piezoelectric driving signal PDS having a positive polarity and a negative polarity by amplifying the piezoelectric audio signal PAS and may be configured to supply (or transfer) the piezoelectric driving signal PDS having the positive polarity and the negative polarity to the vibration apparatus 10.

The first amplifier circuit 131 according to an embodiment of the present disclosure may receive (or apply) the piezoelectric audio signal PAS from the signal conversion circuit 120 and may generate the piezoelectric driving signal PDS by amplifying the piezoelectric audio signal PAS within a range of an allowable voltage. Accordingly, the vibration apparatus 10 may vibrate (or displace) by the piezoelectric driving signal PDS based on the piezoelectric audio signal PAS where an overcurrent is limited by the signal conversion circuit 120 in the high-pitched sound band, and thus, an overcurrent phenomenon and a clipping phenomenon occurring in the high-pitched sound band (or high frequency region) may be prevented.

The one or more (or plurality of) second amplifier circuits 132-1 to 132-n may amplify the one or more (or plurality of) second input audio signals IAS2-1 to IAS2-n to generate the one or more (or plurality of) actuator driving signals ADS1 to ADSn, based on a predetermined gain value. For example, the one or more (or plurality of) second amplifier circuits 132-1 to 132-n may amplify the one or more (or plurality of) second input audio signals IAS2-1 to IAS2-n to generate the one or more (or plurality of) actuator driving signals ADS1 to ADSn having a positive polarity and a negative polarity and may be configured to supply (or transfer) the one or more (or plurality of) actuator driving signals ADS1 to ADSn having the positive polarity and the negative polarity to the one or more (or plurality of) actuators 30-1 to 30-n.

In the sound driving circuit 101 according to another embodiment of the present disclosure, the audio processor 110, the signal conversion circuit 120, and the amplifier circuit 130 may be mounted on one printed circuit board (PCB). For example, in the PCB, a signal line 101L between the audio processor 110 and the first amplifier circuit 131 may be disconnected or there is not a signal line between the audio processor 110 and the first amplifier circuit 131. Accordingly, the first input audio signal IAS1 output from the audio processor 110 may not be supplied to the first amplifier circuit 131 (e.g., through the disconnected signal line 101L) and may be supplied to only the signal conversion circuit 120.

The vibration apparatus 10 may vibrate (or displace) based on the piezoelectric driving signal PDS applied from the first amplifier circuit 131 in the sound driving circuit 101 (or the amplifier circuit 130 of the sound driving circuit 101) to output (or generate) the sound (or vibration or sound wave), may prevent an overcurrent phenomenon and a clipping phenomenon occurring in the high-pitched sound band (or high frequency region), and may improve the dip phenomenon in the first pitched sound band and the peak phenomenon in the second pitched sound band, thereby enhancing a sound characteristic and/or a sound pressure level characteristic.

Each of the plurality of actuators 30-1 to 30-n may be configured to generate (or output) a sound (or a vibration) by vibrating (or driving) based on the actuator driving signals ADS1 to ADSn applied from a corresponding second amplifier circuit of the plurality of second amplifier circuits 132-1 to 132-n in the sound driving circuit 101 (or the amplifier circuit 130 of the sound driving circuit 101).

In the sound driving circuit 101 according to another embodiment of the present disclosure, the audio processor 110 and the amplifier circuit 130 may be considered as a conventional sound driving circuit of a speaker. For example, the sound driving circuit 101 according to another embodiment of the present disclosure may include the signal conversion circuit 120 connected between the audio processor 110 and the amplifier circuit 130 in the conventional sound driving circuit of the speaker. Accordingly, because the sound driving circuit 101 according to another embodiment of the present disclosure includes the signal conversion circuit 120 added to the conventional sound driving circuit of the speaker, the sound driving circuit 101 may drive (or vibrate or displace) both an actuator including a magnet and a coil and the vibration apparatus 10 of a piezoelectric type and may prevent an overcurrent phenomenon and a clipping phenomenon from occurring in the high-pitched sound band (or high frequency region) when the vibration apparatus 10 is being driven (or vibrated or displaced).

FIG. 5 illustrates a sound apparatus according to another embodiment of the present disclosure. For example, FIG. 5 illustrates an embodiment where a preamplifier circuit is additionally configured in the driving circuit part described above with reference to FIG. 4. In the following description, therefore, a preamplifier circuit will be described in detail, the other elements may be substantially a same as that of descriptions described above with reference to FIG. 4, and thus, like reference numerals refer to like elements and its repeated descriptions may be omitted or will be briefly given below.

With reference to FIG. 5, in a sound apparatus according to another embodiment (or a fourth embodiment) of the present disclosure, the sound driving circuit 101 of the driving circuit part 100 may include a preamplifier circuit 140, a signal conversion circuit 120, and an amplifier circuit 130, and may further include an audio processor 110.

The audio processor 110 may be configured to supply (or transfer) a first audio signal AS1 and one or more (or a plurality of) second audio signals AS2-1 to AS2-n to the preamplifier circuit 140. For example, the audio processor 110 may generate the first audio signal AS1 and the one or more (or a plurality of) second audio signals AS2-1 to AS2-n based on a sound source SS input based on control by a host system (or host controller). The audio processor 110 may be configured to supply (or transfer) the first audio signal AS1 and the one or more (or plurality of) second audio signals AS2-1 to AS2-n to the preamplifier circuit 140.

The audio processor 110 according to an embodiment of the present disclosure may be configured to generate the plurality of second audio signals AS2-1 to AS2-n to supply (or transfer) the plurality of second audio signals AS2-1 to AS2-n to the preamplifier circuit 140, based on the sound source SS. For example, the plurality of second audio signals AS2-1 to AS2-n may be equal to or different from one another.

The preamplifier circuit 140 may amplify the first audio signal AS1 input thereto to generate the first input audio signal IAS1. For example, the preamplifier circuit 140 may be configured to generate a first input audio signal IAS1 by primarily amplifying the first audio signal AS1 input from the audio processor 110, based on a predetermined gain value. The preamplifier circuit 140 may be configured to supply (or transfer) the first input audio signal IAS1 to the signal conversion circuit 120.

The preamplifier circuit 140 may amplify the one or more (or a plurality of) second audio signals AS2-1 to AS2-n input thereto to generate one or more (or a plurality of) second input audio signals IAS2-1 to IAS2-n. For example, the preamplifier circuit 140 may be configured to generate the one or more (or plurality of) second input audio signals IAS2-1 to IAS2-n by primarily amplifying the one or more (or plurality of) second audio signals AS2-1 to AS2-n input from the audio processor 110, based on a predetermined gain value. The preamplifier circuit 140 may be configured to supply (or transfer) the one or more (or plurality of) second input audio signals IAS2-1 to IAS2-n to the amplifier circuit 130.

The preamplifier circuit 140 according to an embodiment of the present disclosure may include a first preamplifier circuit 141 and one or more (or a plurality of) second preamplifier circuit 142-1 to 142-n.

The first preamplifier circuit 141 may amplify the first audio signal AS1 input thereto to generate the first input audio signal IAS1. For example, the first preamplifier circuit 141 may generate the first input audio signal IAS1 by primarily amplifying the first audio signal AS1 input from the audio processor 110, based on the predetermined gain value. The first preamplifier circuit 141 may be configured to supply (or transfer) the first input audio signal IAS1 to the signal conversion circuit 120.

The one or more (or plurality of) second preamplifier circuit 142-1 to 142-n may amplify the one or more (or plurality of) second audio signals AS2-1 to AS2-n input thereto to generate the one or more (or plurality of) second input audio signals IAS2-1 to IAS2-n. For example, the one or more (or plurality of) second preamplifier circuit 142-1 to 142-n may be configured to generate the one or more (or plurality of) second input audio signals IAS2-1 to IAS2-n by primarily amplifying the one or more (or plurality of) second audio signals AS2-1 to AS2-n input from the audio processor 110, based on a predetermined gain value. The one or more (or plurality of) second preamplifier circuit 142-1 to 142-n may be configured to supply (or transfer) the one or more (or plurality of) second input audio signals IAS2-1 to IAS2-n to the amplifier circuit 130.

The signal conversion circuit 120 may receive the first input audio signal IAS1 output from the preamplifier circuit 140 (or the first preamplifier circuit 141) and may be configured to convert the received first input audio signal IAS1 into a piezoelectric audio signal PAS. Except for that the signal conversion circuit 120 receives the first input audio signal IAS1 output from the preamplifier circuit 140, the signal conversion circuit 120 may be a same or substantially a same as the signal conversion circuit 120 described above with reference to FIG. 4, and thus, its repeated descriptions are omitted. The descriptions of the signal conversion circuit 120 described above with reference to FIG. 4 may be included in descriptions of a signal conversion circuit 120 illustrated in FIG. 5. The signal conversion circuit 120 may be configured to supply (or transfer) the piezoelectric audio signal PAS to the amplifier circuit 130.

The amplifier circuit 130 may amplify the one or more (or plurality of) second input audio signals IAS2-1 to IAS2-n supplied from the preamplifier circuit 140 to generate one or more (or a plurality of) actuator driving signals ADS1 to ADSn and amplify the piezoelectric audio signal PAS supplied from the signal conversion circuit 120 to generate a piezoelectric driving signal PDS.

Except for that the amplifier circuit 130 receives the one or more (or plurality of) second input audio signals IAS2-1 to IAS2-n output from the preamplifier circuit 140, the amplifier circuit 130 may be a same or substantially a same as the amplifier circuit 130 described above with reference to FIG. 4, and thus, its repeated descriptions may be omitted or will be briefly given below. The descriptions of the amplifier circuit 130 described above with reference to FIG. 4 may be included in descriptions of the amplifier circuit 130 illustrated in FIG. 5.

The amplifier circuit 130 according to an embodiment of the present disclosure may include a first amplifier circuit 131 and one or more (or a plurality of) second amplifier circuits 132-1 to 132-n.

The first amplifier circuit 131 may generate the piezoelectric driving signal PDS by amplifying the piezoelectric audio signal PAS output from the signal conversion circuit 120, based on a predetermined gain value. For example, the first amplifier circuit 131 may generate the piezoelectric driving signal PDS having a positive polarity and a negative polarity by amplifying the piezoelectric audio signal PAS and may be configured to supply (or transfer) the piezoelectric driving signal PDS having the positive polarity and the negative polarity to the vibration apparatus 10.

The one or more (or plurality of) second amplifier circuits 132-1 to 132-n may amplify the one or more (or plurality of) second input audio signals IAS2-1 to IAS2-n supplied from the preamplifier circuit 140 to generate the one or more (or plurality of) actuator driving signals ADS1 to ADSn, based on a predetermined gain value. For example, the one or more (or plurality of) second amplifier circuits 132-1 to 132-n may amplify the one or more (or plurality of) second input audio signals IAS2-1 to IAS2-n to generate the one or more (or plurality of) actuator driving signals ADS1 to ADSn having a positive polarity and a negative polarity and may be configured to supply (or transfer) the one or more (or plurality of) actuator driving signals ADS1 to ADSn having the positive polarity and the negative polarity to the one or more (or plurality of) actuators 30-1 to 30-n.

In the sound driving circuit 101 according to another embodiment of the present disclosure, the audio processor 110, the signal conversion circuit 120, the amplifier circuit 130, and the preamplifier circuit 140 may be mounted on one printed circuit board (PCB). For example, in the PCB, a signal line 101L between the first preamplifier circuit 141 of the preamplifier circuit 140 and the first amplifier circuit 131 of the amplifier circuit 130 may be disconnected or there is not a signal line between the first preamplifier circuit 141 and the first amplifier circuit 131. Accordingly, the first input audio signal IAS1 output from the preamplifier circuit 140 may not be supplied to the amplifier circuit 130 (e.g., through the disconnected signal line 101L) and may be supplied to only the signal conversion circuit 120.

The vibration apparatus 10 may vibrate (or displace) based on the piezoelectric driving signal PDS applied from the first amplifier circuit 131 in the sound driving circuit 101 (or the amplifier circuit 130 of the sound driving circuit 101) to output (or generate) the sound (or vibration or sound wave), may prevent an overcurrent phenomenon and a clipping phenomenon occurring in the high-pitched sound band (or high frequency region), and may improve the dip phenomenon in the first pitched sound band and the peak phenomenon in the second pitched sound band, thereby enhancing a sound characteristic and/or a sound pressure level characteristic.

Each of the plurality of actuators 30-1 to 30-n may be configured to generate (or output) a sound (or a vibration) by vibrating (or driving) based on the actuator driving signals ADS1 to ADSn applied from a corresponding second amplifier circuit of the plurality of second amplifier circuits 132-1 to 132-n in the sound driving circuit 101 (or the amplifier circuit 130 of the sound driving circuit 101).

In the sound driving circuit 101 according to another embodiment of the present disclosure, the audio processor 110, the amplifier circuit 130, and the preamplifier circuit 140 may be considered as a conventional sound driving circuit of a speaker. For example, the sound driving circuit 101 according to another embodiment of the present disclosure may include the signal conversion circuit 120 connected between the preamplifier circuit 140 and the amplifier circuit 130 in the conventional sound driving circuit of the speaker. Accordingly, because the sound driving circuit 101 according to another embodiment of the present disclosure includes the signal conversion circuit 120 added to the conventional sound driving circuit of the speaker, the sound driving circuit 101 may drive (or vibrate or displace) both an actuator including a magnet and a coil and the vibration apparatus 10 of a piezoelectric type and may prevent an overcurrent phenomenon and a clipping phenomenon from occurring in the high-pitched sound band (or high frequency region) when the vibration apparatus 10 is being driven (or vibrated or displaced).

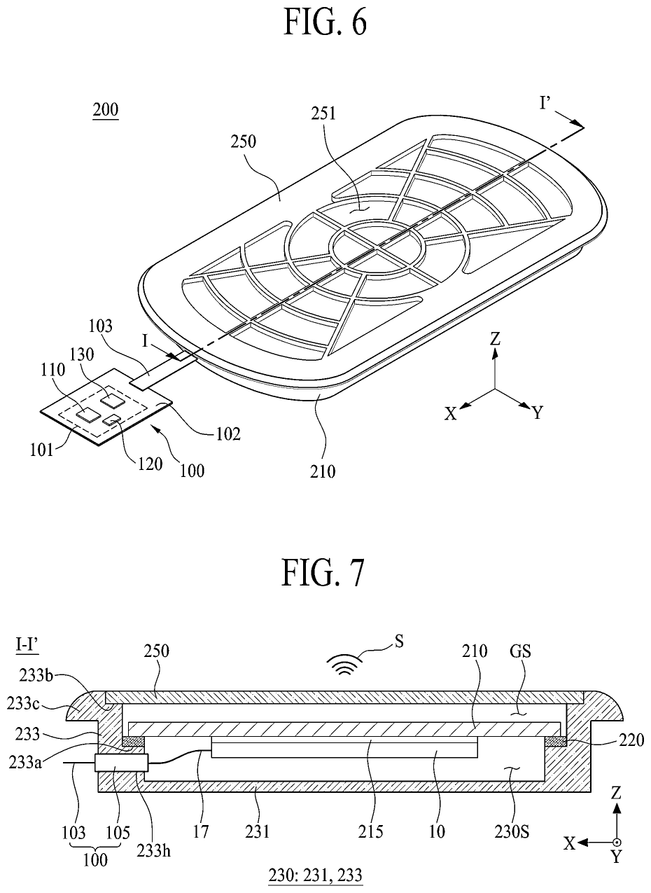

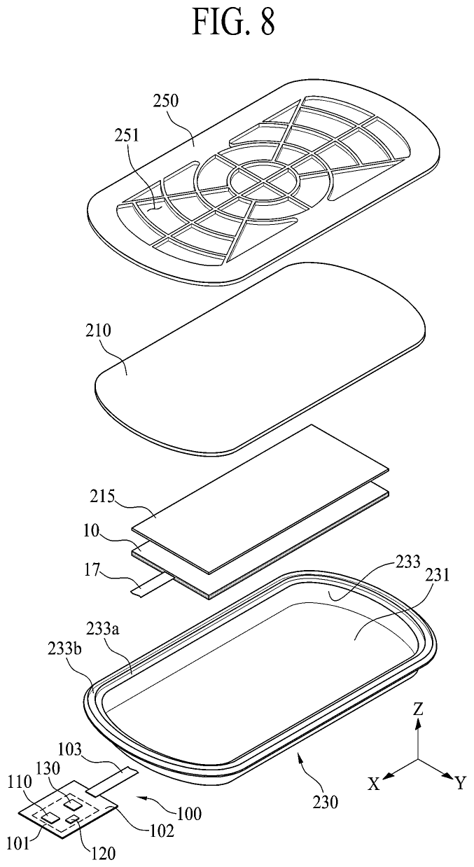

FIG. 6 illustrates a sound apparatus according to another embodiment of the present disclosure. FIG. 7 is a cross-sectional view taken along line I-I′ illustrated in FIG. 6 according to an embodiment of the present disclosure. FIG. 8 is an exploded perspective view illustrating the sound apparatus illustrated in FIG. 6 according to another embodiment of the present disclosure.

With reference to FIGS. 6 to 8, the sound apparatus 200 according to another embodiment of the present disclosure may include a vibration member 210, a supporting member 230, a vibration apparatus 10, and a driving circuit part 100.

The vibration member 210 may generate a vibration or may output a sound (or a sound wave or a sound pressure level) S, based on a vibration (or displacement) of the vibration apparatus 10. For example, the vibration member 210 may be a vibration plate, a sound plate, a diaphragm, a sound output plate, or a sound vibration plate, or the like, but embodiments of the present disclosure are not limited thereto.

The supporting member 230 may be disposed at a periphery portion of the vibration member 210. The supporting member 230 may have an internal space 230S and may be configured to support the vibration member 210. For example, the supporting member 230 may be configured to accommodate the vibration member 210. For example, the supporting member 230 may be a case, an outer case, a case member, a housing, a housing member, a cabinet, or an enclosure, but embodiments of the present disclosure are not limited thereto.

The supporting member 230 according to an embodiment of the present disclosure may be configured to be transparent, semitransparent, or opaque. For example, the supporting member 230 may include one or more of a metal material and a nonmetal material (or a composite nonmetal material), but embodiments of the present disclosure are not limited thereto. For example, the supporting member 230 may include one or more materials of a metal material, plastic, and wood, but embodiments of the present disclosure are not limited thereto.

The supporting member 230 according to an embodiment of the present disclosure may include a bottom part 231 and a sidewall part 233.

The bottom part 231 may be disposed to be spaced apart from the vibration member 210. The bottom part 231 may be disposed to face a rear surface of the vibration member 210.

The sidewall part 233 may be configured or disposed at a periphery portion of the bottom part 231. For example, the sidewall part 233 may be vertically connected to the periphery portion of the bottom part 231. For example, the sidewall part 233 may include a structure bent from the periphery portion of the bottom part 231, but embodiments of the present disclosure are not limited thereto.

The sidewall part 233 may be configured to support the vibration member 210. For example, the sidewall part 233 may be configured to support a periphery portion of the vibration member 210. For example, the sidewall part 233 may be configured to support the vibration member 210 and surround a lateral surface of the vibration member 210.

According to an embodiment of the present disclosure, the sidewall part 233 may be integrated with the bottom part 231. For example, the bottom part 231 and the sidewall part 233 may be integrated as one body (a single body), and thus, the internal space 200S surrounded by the sidewall part 233 may be provided over the bottom part 231. Accordingly, the supporting member 230 may include a box shape where one side (or an upper side) is opened by the bottom part 231 and the sidewall part 233.

The sidewall part 233 according to an embodiment of the present disclosure may include a first supporting surface 233a. The first supporting surface 233a may be configured to support the periphery portion of the vibration member 210. For example, the first supporting surface 233a may protrude from an inner surface of the sidewall part 233. The vibration member 210 may be connected or coupled to the first supporting surface 233a by using a coupling member 220. For example, a rear periphery portion of the vibration member 210 may be connected or coupled to the first supporting surface 233a by using the coupling member 220.

The vibration apparatus 10 may be configured to vibrate the vibration member 210. The vibration apparatus 10 may be a piezoelectric-type vibration apparatus including a piezoelectric material.

The vibration apparatus 10 may be disposed or configured at any one of a first surface (or a front surface or an upper surface) and a second surface (or a rear surface or a lower surface) opposite to the first surface of the vibration member 210. For example, the vibration apparatus 10 may be disposed or configured at the second surface of the vibration member 210, but embodiments of the present disclosure are not limited thereto. For example, the vibration apparatus 10 may be disposed or configured at each of the first surface and the second surface of the vibration member 210. For example, the vibration apparatus 10 may be disposed or configured at one or more of the first surface and the second surface of the vibration member 210.

The vibration apparatus 10 may be connected or coupled to the vibration member 110 by a connection member 215. For example, the vibration apparatus 10 may be connected or coupled to one or more of the first surface and the second surface of the vibration member 210 by using the connection member 215. Accordingly, the vibration member 210 may vibrate based on a vibration (or displacement) of the vibration apparatus 10 to generate one or more of a vibration and a sound. For example, the vibration apparatus 10 may generate one or more of a vibration and a sound using the vibration member 210 as a vibration plate.

The driving circuit part 100 may be electrically connected to the vibration apparatus 10 through a signal supply member 17. The driving circuit part 100 may be configured to apply the piezoelectric driving signal to the vibration apparatus 10 through the signal supply member 17. The driving circuit part 100 may include the sound driving circuit 101 described above with reference to FIGS. 1 to 5, and thus, its repeated descriptions are omitted.

The vibration apparatus 10 may vibrate (or displace) based on the piezoelectric driving signal applied through the signal supply member 17 from the sound driving circuit 101 to vibrate the vibration member 210. Accordingly, the vibration apparatus 10 may prevent an overcurrent phenomenon and a clipping phenomenon occurring in the high-pitched sound band (or high frequency region), and may improve the dip phenomenon in the first pitched sound band and the peak phenomenon in the second pitched sound band, thereby enhancing a sound characteristic and/or a sound pressure level characteristic.

The driving circuit part 100 according to an embodiment of the present disclosure may further include a signal cable 103 and a connector 105.

The signal cable 103 may be electrically connected to a printed circuit board (PCB) 102 of the driving circuit part 100.

The connector 105 may be disposed or configured at the supporting member 230 and may be configured to be electrically connected to the signal cable 103. A portion of the connector 105 may pass through the sidewall part 233 of the supporting member 230 and may be accommodated into the internal space 230S. For example, the connector 105 may be inserted (or accommodated) into a portion of the sidewall part 233 of the supporting member 230. For example, the supporting member 230 may further include a connector inserting hole (or a connector accommodating hole) 233h which is provided at the sidewall part 233 so that a portion (or an inner side portion) of the connector 105 is inserted (or accommodated) therein. For example, a waterproof member (or waterproof adhesive or waterproof tape) may be disposed or interposed between the connector inserting hole and the connector 105.

The sound apparatus 200 according to another embodiment of the present disclosure may further include a cover 250.

The cover 250 may be configured to cover the vibration member 210. The cover 250 may be configured to protect the vibration member 210 and the vibration apparatus 10. For example, the cover 250 may be supported by the supporting member 230 to cover the first surface of the vibration member 210. For example, the cover 250 may be supported by the supporting member 230 to be spaced apart from the first surface of the vibration member 210. For example, the cover 250 may be supported by the supporting member 230 with a gap space GS therebetween.

The sidewall part 233 according to an embodiment of the present disclosure may include a second supporting surface 233b. The second supporting surface 233b may be configured to support a periphery portion of the cover 250. For example, the second supporting surface 233b may be formed concavely from an inner side surface and an uppermost surface of the sidewall part 233. The second supporting surface 233b may be between the uppermost surface of the sidewall part 233 and the first supporting surface 233a.

The supporting member 230 according to an embodiment of the present disclosure may further include a protrusion part 233c. For example, the protrusion part 233c may protrude from an upper outer surface of the sidewall part 233 to have a predetermined width.

The cover 250 according to an embodiment of the present disclosure may be detachably coupled to the sidewall part 233 of the supporting member 230 by a hook coupling scheme, but embodiments of the present disclosure are not limited thereto. For example, the cover 250 according to another embodiment of the present disclosure may be attached to the second supporting surface 233b of the supporting member 230 by using an attachment member.

The cover 250 according to an embodiment of the present disclosure may include a sound emission part (or a sound emission port) 251. The sound emission part 251 may be formed to vertically pass through the cover 250 along a thickness direction Z of the cover 250. Accordingly, a sound (or sound wave) S generated by a vibration (or displacement) of the vibration member 210 based on a vibration (or displacement) of the vibration apparatus 10 may be output to an outside through the sound emission part 251 of the cover 250.

The sound emission part 251 according to an embodiment of the present disclosure may include one or more holes formed to overlap (or correspond to) a center of the vibration apparatus 10. The sound emission part 251 according to another embodiment of the present disclosure may include one or more holes based on a mesh structure or a radial mesh structure.

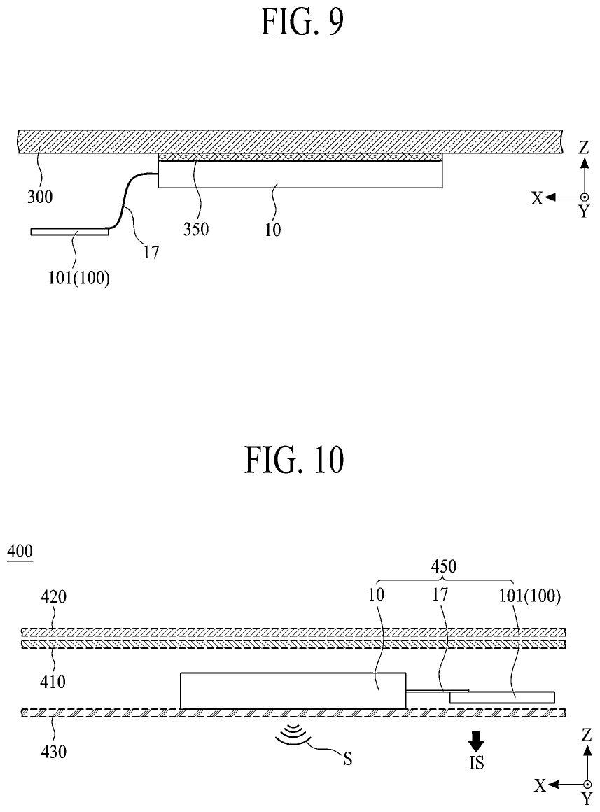

FIG. 9 is a cross-sectional view illustrating an apparatus according to an embodiment of the present disclosure.

With reference to FIG. 9, an apparatus according to an embodiment of the present disclosure may be an apparatus for outputting a sound. For example, the apparatus according to an embodiment of the present disclosure may be an apparatus for outputting one or more of a sound and a vibration. For example, the apparatus according to an embodiment of the present disclosure may implement or realize a display apparatus, a sound apparatus, a sound output apparatus, a vibration apparatus, a vibration generating apparatus, a sound bar, a sound system, a sound apparatus for electronic apparatuses, a sound apparatus for displays, a sound apparatus for vehicular apparatuses, or a sound bar for vehicular apparatuses, or the like. For example, a vehicular apparatus may include one or more seats and one or more glass windows. For example, the vehicular apparatus may include a vehicle, a train, a ship, or an aircraft, but embodiments of the present disclosure are not limited thereto. In addition, the apparatus according to an embodiment of the present disclosure may implement or realize an analog signage or a digital signage, or the like such as an advertising signboard, a poster, or a noticeboard, or the like.

The apparatus according to an embodiment of the present disclosure may include a passive vibration member 300, a vibration apparatus 10, and a driving circuit part 100.

The passive vibration member 300 may vibrate based on a vibration (or displacement) of the vibration apparatus 10. For example, the passive vibration member 300 may generate one or more of a vibration and a sound based on driving of the vibration apparatus 10.

The passive vibration member 300 according to an embodiment of the present disclosure may be a display panel including a display area (or a screen) having a plurality of pixels which implement a black/white or color image. Thus, the passive vibration member 300 may generate one or more of a vibration and a sound based on driving of the vibration apparatus 10. For example, the passive vibration member 300 may vibrate based on vibration of the vibration apparatus 10 while a display area is displaying an image, and thus, may generate or output a sound synchronized with the image displayed on the display area. For example, the passive vibration member 300 may be a vibration object, a display member, a display panel, a signage panel, a vibration plate, a passive vibration plate, a front cover, a front member, a vibration panel, a sound panel, a passive vibration panel, a sound output plate, a sound vibration plate, or an image screen, or the like, but embodiments of the present disclosure are not limited thereto.

The passive vibration member 300 according to another embodiment of the present disclosure may be configured with a material having a material characteristic suitable for being vibrated by the vibration apparatus 10 to output a sound. The passive vibration member 300 may include a metal material or a nonmetal material (or a composite nonmetal material), but embodiments of the present disclosure are not limited thereto. For example, the passive vibration member 300 may include one or more materials of metal, plastic, paper, wood, fiber, cloth, leather, glass, carbon, and a mirror, but embodiments of the present disclosure are not limited thereto. For example, the paper may be cone paper for speakers. For example, the cone paper may be pulp or foamed plastic, or the like, but embodiments of the present disclosure are not limited thereto.

The passive vibration member 300 according to another embodiment of the present disclosure may include a display panel including a pixel displaying an image, or may include a non-display panel. For example, the passive vibration member 300 may include one or more of a display panel including a pixel displaying an image, a screen panel on which an image is projected from a display apparatus, a lighting panel, a signage panel, a vehicular interior material, a vehicular exterior material, a vehicular glass window, a vehicular seat interior material, a vehicular ceiling material, a building ceiling material, a building interior material, a building glass window, an aircraft interior material, an aircraft glass window, and a mirror, but embodiments of the present disclosure are not limited thereto. For example, the non-display panel may be a light-emitting diode lighting panel (or apparatus), an organic light-emitting lighting panel (or apparatus), an inorganic light-emitting lighting panel (or apparatus), a mini light-emitting diode panel (or apparatus), or a micro light-emitting diode panel (or apparatus), but embodiments of the present disclosure are not limited thereto.

The vibration apparatus 10 may be configured to vibrate the passive vibration member 300. The vibration apparatus 10 may be a piezoelectric-type vibration apparatus including a piezoelectric material. For example, the vibration apparatus 10 may be configured to be transparent, semitransparent, or opaque.

The vibration apparatus 10 may be connected or coupled to the passive vibration member 300 by a connection member 350. For example, the vibration apparatus 10 may be connected to a rear surface of the passive vibration member 300 by using the connection member 350. Accordingly, the passive vibration member 300 may vibrate based on a vibration (or displacement) of the vibration apparatus 10 to generate one or more of a vibration and a sound. For example, the vibration apparatus 10 may generate one or more of a vibration and a sound using the passive vibration member 300 as a vibration plate.

The driving circuit part 100 may be electrically connected to the vibration apparatus 10 through a signal supply member 17. The driving circuit part 100 may be configured to apply the piezoelectric driving signal to the vibration apparatus 10 through the signal supply member 17. The driving circuit part 100 may include the sound driving circuit 101 described above with reference to FIGS. 1 to 5, and thus, its repeated descriptions are omitted.

The vibration apparatus 10 may vibrate (or displace) based on the piezoelectric driving signal applied through the signal supply member 17 from the sound driving circuit 101 to vibrate the passive vibration member 300. Accordingly, the vibration apparatus 10 may prevent an overcurrent phenomenon and a clipping phenomenon occurring in the high-pitched sound band (or high frequency region), and may improve the dip phenomenon in the first pitched sound band and the peak phenomenon in the second pitched sound band, thereby enhancing a sound characteristic and/or a sound pressure level characteristic.

FIG. 10 is a cross-sectional view illustrating a vehicular apparatus according to an embodiment of the present disclosure.

With reference to FIG. 10, a vehicular apparatus 400 according to an embodiment of the present disclosure may be a vehicular apparatus which includes one or more seats and one or more windows. For example, the vehicular apparatus 400 may include a vehicle, a train, a ship, or an aircraft, or the like, but embodiments of the present disclosure are not limited thereto.

The vehicular apparatus 400 may include a main structure 410, an exterior material 420, and an interior material 430.

The main structure 410 may be a vehicle body, a vehicle structure, or a frame structure, or the like, but embodiments of the present disclosure are not limited thereto. For example, the main structure 410 may include a main frame, a sub-frame, a side frame, a door frame, an under-frame, and a seat frame, or the like, but embodiments of the present disclosure are not limited thereto.

The exterior material 420 may be configured to cover the main structure 410. For example, the exterior material 420 may be configured to cover an outer portion of the main structure 410. In the following description, the exterior material 420 may be a vehicle exterior material 420, and may be used interchangeably. For example, the vehicle exterior material 420 may include at least one or more of a hood panel, a front fender panel, a dash panel, a pillar panel, a trunk panel, a roof panel (or ceiling), a floor panel, a door panel, a door inner panel, and a door outer panel, a front bumper, a rear bumper, a spoiler, a headlight, a taillight, a fog light, and a vehicle body bottom, but embodiments of the present disclosure are not limited thereto.

The vehicle exterior material 420 according to an embodiment of the present disclosure may include at least one or more of a planar portion (or a flat portion) and a curved portion (or a flexural portion or an uneven portion). For example, the vehicle exterior material 420 may have a structure corresponding to a structure of a corresponding main structure 410, or may have a structure which differs from a structure of a corresponding main structure 410.

In the following description, the interior material 430 may be a vehicle interior material 430, and may be used interchangeably. The vehicle interior material 430 may include all elements (or components) configuring an inner portion of the vehicular apparatus 400, or may include all elements disposed at an interior space (or an indoor space) IS of the vehicular apparatus 400. For example, the vehicle interior material 430 may be an interior member or an interior finish material of the vehicular apparatus 400, but embodiments of the present disclosure are not limited thereto.

The vehicle interior material 430 according to an embodiment of the present disclosure may be configured to cover one or more of main structure 410 and the vehicle exterior material 420 in the interior space IS. For example, the vehicle interior material 430 may cover one or more of main structure 410 and the vehicle exterior material 420 in the interior space IS of the vehicular apparatus 400 and may be configured to be exposed at the interior space IS of the vehicular apparatus 400.

The vehicle interior material 430 according to an embodiment of the present disclosure may be configured to be exposed at the inner portion and/or the interior space IS of the vehicular apparatus 400. For example, the vehicle interior material 430 may be configured to cover one surface (or an interior surface) of one or more of a main frame (or a vehicle body), a side frame (or a side body), a door frame (or a door body), a handle frame (or a steering hub), and a seat frame, which are exposed at the interior space IS of the vehicular apparatus 400.

The vehicle interior material 430 according to an embodiment of the present disclosure may include a dashboard, a pillar interior material (or a pillar trim), a floor interior material (or a floor carpet), a roof interior material (or a headliner), a door interior material (or a door trim), a handle interior material (or a steering cover), a seat interior material, a rear package interior material (or a back seat shelf), an overhead console (or an illumination interior material), a rear view mirror, a glove box, and a sun visor, or the like, but embodiments of the present disclosure are not limited thereto.

The vehicle interior material 430 according to an embodiment of the present disclosure may include one or more of metal, wood, rubber, plastic, glass, fiber, cloth, paper, a mirror, leather, and carbon, but embodiments of the present disclosure are not limited thereto. The vehicle interior material 430 including a plastic material may be an injection material which is implemented by an injection process using a thermoplastic resin or a thermosetting resin, but embodiments of the present disclosure are not limited thereto. The vehicle interior material 430 including a fiber material may include at least one or more of a plastic composite fiber, a carbon fiber (or an aramid fiber), and a natural fiber, but embodiments of the present disclosure are not limited thereto. The vehicle interior material 430 including the cloth material may include a textile sheet, a knit sheet, or a nonwoven fabric, or the like, but embodiments of the present disclosure are not limited thereto. For example, the paper may be cone paper for speakers. For example, the cone paper may be pulp or foamed plastic, or the like, but embodiments of the present disclosure are not limited thereto. The vehicle interior material 430 including a leather material may include natural leather or artificial leather, but embodiments of the present disclosure are not limited thereto.

The vehicle interior material 430 according to an embodiment of the present disclosure may include at least one or more of a planar portion (or a flat portion) and a curved portion (or a flexural portion or an uneven portion). For example, the vehicle interior material 430 may have a structure corresponding to a structure (or an inner surface structure) of a corresponding main structure 410, or may have a structure which differs from a structure of a corresponding main structure 410.

The vehicular apparatus 400 according to an embodiment of the present disclosure may include one or more sound generating apparatuses 450.

The one or more sound generating apparatuses 450 may be configured to output a sound from one or more of a region between the vehicle exterior material 420 and the vehicle interior material 430, the vehicle exterior material 420 and the vehicle interior material 430.

According to an embodiment of the present disclosure, the one or more sound generating apparatuses 450 may be disposed at the vehicle interior material 430. The one or more sound generating apparatuses 450 may vibrate (or directly vibrate) the vehicle interior material 430 to generate a sound S based on a vibration of the vehicle interior material 430. For example, the one or more sound generating apparatuses 450 may be configured to vibrate the vehicle interior material 430 to output the sound S toward the inner portion and/or the interior space IS of the vehicular apparatus 400. Thus, the one or more sound generating apparatuses 450 may use the vehicle interior material 430 as a sound vibration plate. The vehicle interior material 430 may be a vibration plate, a sound vibration plate, or a sound generating plate for outputting the sound S, but embodiments of the present disclosure are not limited thereto. For example, the vehicle interior material 430 may have a size which is greater than that of the one or more sound generating apparatuses 450, but embodiments of the present disclosure are not limited thereto.

According to an embodiment of the present disclosure, the one or more sound generating apparatuses 450 may be disposed in at least one or more of a dashboard, a pillar interior material, a floor interior material, a roof interior material, a door interior material, a handle interior material, and a seat interior material, or may be disposed in or connected to (or coupled to) at least one or more of a rear package interior material, an overhead console, a rear view mirror, a glove box, and a sun visor. For example, the one or more sound generating apparatuses 450 may vibrate (or directly vibrate) at least one or more of the dashboard, the pillar interior material, the floor interior material, the roof interior material, the door interior material, the handle interior material, the seat interior material, the rear package interior material, the overhead console, the rear view mirror, the glove box, and the sun visor to output the sound S toward the inner portion and/or the interior space IS of the vehicular apparatus 400.

According to an embodiment of the present disclosure, the one or more sound generating apparatuses 450 may be disposed in or connected to at least one or more regions (or portions) of the vehicle interior material 430. The one or more sound generating apparatuses 450 may vibrate the at least one or more regions (or portions) of the vehicle interior material 430 to output a realistic sound S and/or stereo sound including a multichannel toward the interior space IS of the vehicular apparatus 400.

According to an embodiment of the present disclosure, the one or more sound generating apparatuses 450 may be disposed in one or more of a region between the vehicle interior material 430 and the main structure 410 and a region between the vehicle interior material 430 and the vehicle exterior material 420, and may be configured to output a sound S.

According to an embodiment of the present disclosure, the one or more sound generating apparatuses 450 may be disposed in one or more of the region between the vehicle interior material 430 and the main structure 410 and the region between the vehicle interior material 430 and the vehicle exterior material 420, and may indirectly or directly vibrate one or more of the main structure 410, the vehicle exterior material 420, and the vehicle interior material 430 to output a sound S. For example, one or more of the main structure 410, the vehicle exterior material 420, and the vehicle interior material 430 may output a sound S based on driving (or vibration or displacement) of the one or more sound generating apparatuses 450.

According to an embodiment of the present disclosure, the one or more sound generating apparatuses 450 may be disposed in one or more of a region (or a first region) between the main structure 410 and the vehicle exterior material 420, a region (or a second region) between the main structure 410 and the vehicle interior material 430, the vehicle exterior material 420, and the vehicle interior material 430, and may be configured to output a sound. For example, the one or more sound generating apparatuses 450 may be disposed in one or more of the region (or first region) between the main structure 410 and the vehicle exterior material 420, the region (or second region) between the main structure 410 and the vehicle interior material 430, the vehicle exterior material 420, and the vehicle interior material 430, and may indirectly or directly vibrate one or more of the main structure 410, the vehicle exterior material 420, and the vehicle interior material 430 to output a sound.

According to an embodiment of the present disclosure, one or more of the vehicle exterior material 420 and the vehicle interior material 430 of the vehicular apparatus 400 may be a vibration plate, a sound vibration plate, or a sound generating plate, for outputting the sound S. For example, each of the vehicle exterior material 420 and the vehicle interior material 430 for outputting the sound S may have a size (or an area) which is greater than that of the one or more sound generating apparatuses 450, and thus, may perform a function of a large-area vibration plate, a large-area sound vibration plate, or a large-area sound generating plate, thereby enhancing a sound characteristic and/or a sound pressure level characteristic of a pitched sound band including a low-pitched sound band generated by the sound generating apparatus 450. For example, a frequency of a sound of the low-pitched sound band may be 300 Hz or less, 400 Hz or less, or 500 Hz or less, but embodiments of the present disclosure are not limited thereto.

The one or more sound generating apparatuses 450 according to an embodiment of the present disclosure may include a vibration apparatus 10 and a driving circuit part 100.

The vibration apparatus 10 may be a piezoelectric-type vibration apparatus including a piezoelectric material.

The vibration apparatus 10 according to an embodiment of the present disclosure may be disposed in one or more of a region between the vehicle interior material 430 and the main structure 410 and a region between the vehicle interior material 430 and the vehicle exterior material 420, and may be configured to output a sound.

The vibration apparatus 10 according to another embodiment of the present disclosure may be disposed in one or more of the region between the vehicle interior material 430 and the main structure 410 and the region between the vehicle interior material 430 and the vehicle exterior material 420, and may indirectly or directly vibrate one or more of the main structure 410, the vehicle exterior material 420, and the vehicle interior material 430 to output a sound S.

The vibration apparatus 10 according to another embodiment of the present disclosure may be disposed in one or more of the region (or first region) between the main structure 410 and the vehicle exterior material 420, the region (or second region) between the main structure 410 and the vehicle interior material 430, the vehicle exterior material 420, and the vehicle interior material 430, and may indirectly or directly vibrate one or more of the main structure 410, the vehicle exterior material 420, and the vehicle interior material 430 to output a sound.

The vibration apparatus 10 according to another embodiment of the present disclosure may be connected or coupled to one or more of the main structure 410, the vehicle exterior material 420, and the vehicle interior material 430 by using a connection member. Accordingly, one or more of the main structure 410, the vehicle exterior material 420, and the vehicle interior material 430 may vibrate based on a vibration (or displacement) of the vibration apparatus 10 to generate (or output) one or more of a vibration and a sound.

The driving circuit part 100 may be electrically connected to the vibration apparatus 10 through a signal supply member 17. The driving circuit part 100 may be configured to apply the piezoelectric driving signal to the vibration apparatus 10 through the signal supply member 17. The driving circuit part 100 may include the sound driving circuit 101 described above with reference to FIGS. 1 to 5, and thus, its repeated descriptions are omitted.

The vibration apparatus 10 may vibrate (or displace) based on the piezoelectric driving signal applied through the signal supply member 17 from the sound driving circuit 101 to vibrate one or more of the vehicle exterior material 420 and the vehicle interior material 430. Accordingly, the vibration apparatus 10 may prevent an overcurrent phenomenon and a clipping phenomenon occurring in the high-pitched sound band (or high frequency region), and may improve the dip phenomenon in the first pitched sound band and the peak phenomenon in the second pitched sound band, thereby enhancing a sound characteristic and/or a sound pressure level characteristic.

The vehicular apparatus 400 according to an embodiment of the present disclosure may further include a woofer speaker which is disposed in at least one or more of the dashboard, the door frame, and the rear package interior material.

The woofer speaker according to an embodiment of the present disclosure may include one or more of a woofer, a mid-woofer, and a sub-woofer, but embodiments of the present disclosure are not limited thereto. For example, the woofer speaker may be a speaker which outputs a sound of about 60 Hz to about 150 Hz, but embodiments of the present disclosure are not limited thereto. Therefore, the woofer speaker may output a sound of about 60 Hz to about 150 Hz, and thus, may enhance a low-pitched sound band characteristic of a sound which is output to an interior space.

The woofer speaker may drive (or vibrate) based on the actuator driving signal applied through the signal supply member 17 from the sound driving circuit 101 of the driving circuit part 100 in the sound apparatus described above with reference to FIGS. 4 and 5, to generate (or output) a sound.

According to an embodiment of the present disclosure, when the vehicular apparatus 400 includes the vibration apparatus 10 and one or more woofer speakers, the sound driving circuit 101 of the driving circuit part 100 may drive (or vibrate) the vibration apparatus 10 and the one or more woofer speakers, respectively, but embodiments of the present disclosure are not limited thereto.

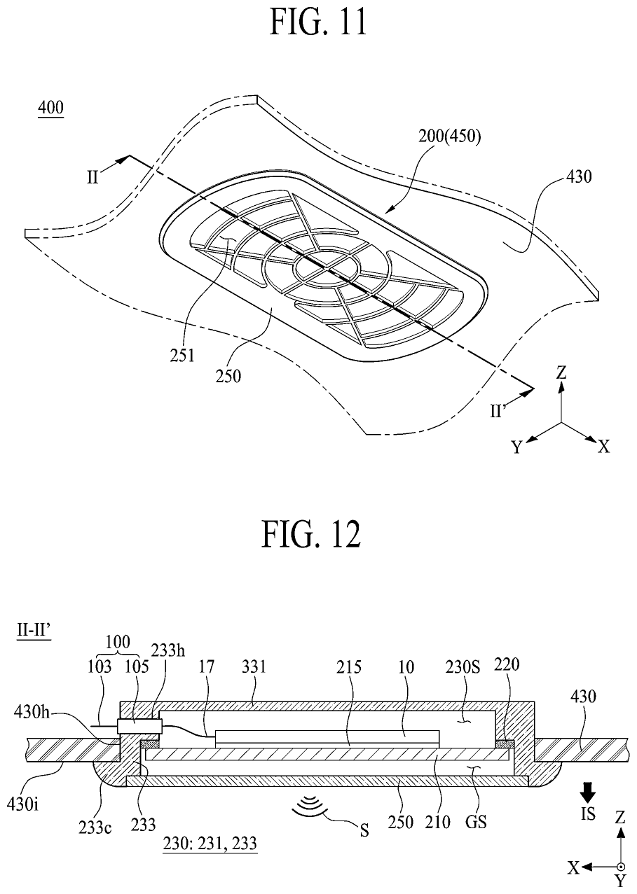

FIG. 11 is a perspective view illustrating a vehicular apparatus according to another embodiment of the present disclosure. FIG. 12 is a cross-sectional view taken along line II-II′ illustrated in FIG. 11 according to an embodiment of the present disclosure.

With reference to FIGS. 11 and 12, a vehicular apparatus 400 according to another embodiment of the present disclosure may include a vehicle interior material 430 and one or more sound generating apparatuses 450.

The vehicle interior material 430 may include all elements (or components) configuring an inner portion of the vehicular apparatus 400, or may include all elements disposed at an interior space IS of the vehicular apparatus 400. The vehicle interior material 430 may be a same or substantially a same as the vehicle interior material 430 described above with reference to FIG. 10, and thus, its repeated descriptions are omitted. For example, the vehicle interior material 430 may be a roof interior material (or a headliner), but embodiments of the present disclosure are not limited thereto.

The one or more sound generating apparatuses 450 may be disposed or mounted on the vehicle interior material 430.

The one or more sound generating apparatuses 450 may include the sound apparatus 200 described above with reference to FIGS. 6 to 8, and thus, its repeated descriptions may be omitted or will be briefly given below.

The sound apparatus 200 may be accommodated into a hole 433h provided in the vehicle interior material 430. For example, the supporting member 230 of the sound apparatus 200 may be accommodated (or inserted) into the hole 433h of the vehicle interior material 430 in the interior space IS of the vehicular apparatus 400. For example, the protrusion part 233c of the supporting member 230 may be in contact with an interior surface 430i of the vehicle interior material 430.

The vibration apparatus 10 of the sound apparatus 200 may vibrate (or displace or drive) based on the piezoelectric driving signal applied through the signal supply member 17 from the sound driving circuit 101 of the driving circuit part 100 to output a sound S toward the interior space IS of the vehicular apparatus 400.

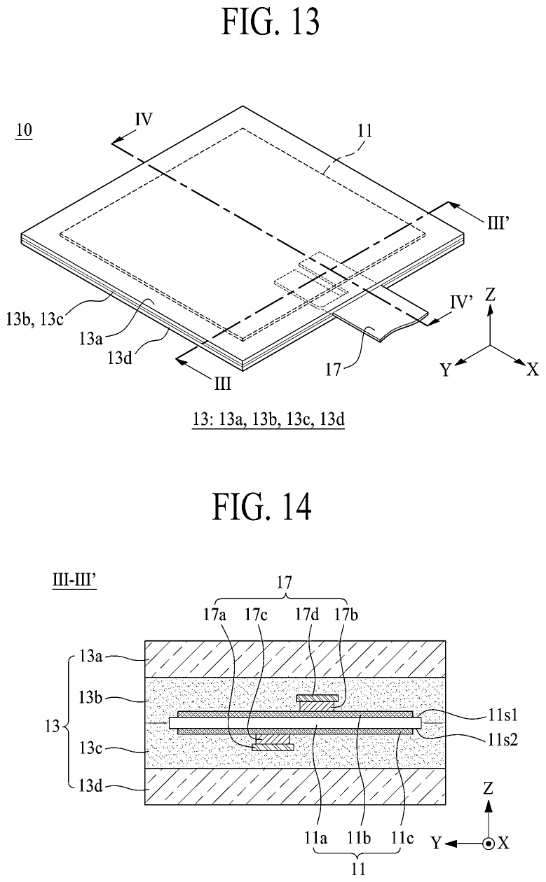

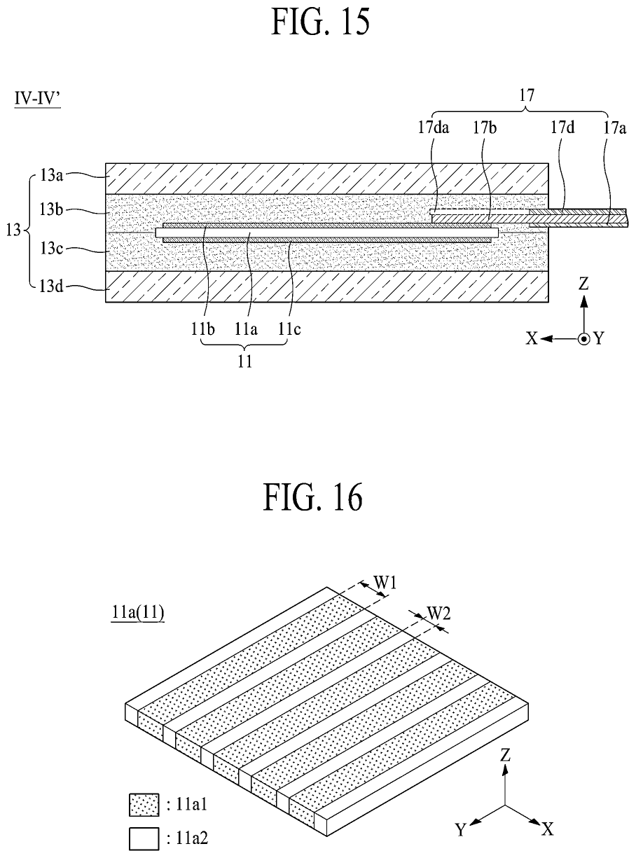

FIG. 13 is a perspective view illustrating a vibration apparatus according to an embodiment of the present disclosure. FIG. 14 is a cross-sectional view taken along line III-III′ illustrated in FIG. 13 according to an embodiment of the present disclosure. FIG. 15 is a cross-sectional view taken along line IV-IV′ illustrated in FIG. 13 according to an embodiment of the present disclosure. In particular, FIGS. 13 to 15 illustrate the vibration apparatus described above with reference to FIGS. 1 to 12.

With reference to FIGS. 13 to 15, the vibration apparatus 10 according to an embodiment of the present disclosure may include a piezoelectric material having a piezoelectric characteristic.

The vibration apparatus 10 may be configured as a ceramic-based piezoelectric material for implementing a relatively strong vibration, or may be configured as a piezoelectric ceramic having a perovskite-based crystal structure.

The vibration apparatus 10 according to an embodiment of the present disclosure may include a vibration part 11.

The vibration part 11 may be configured to vibrate by a piezoelectric effect based on a piezoelectric driving signal. The vibration part 11 may include at least one or more of a piezoelectric inorganic material and a piezoelectric organic material. For example, the vibration part 11 may be a vibration device, a piezoelectric device layer, a piezoelectric structure, a piezoelectric vibration part, or a piezoelectric vibration layer, or the like, but embodiments of the present disclosure are not limited thereto.

The vibration part 11 according to an embodiment of the present disclosure may include a vibration layer 11a, a first electrode layer 11b, and a second electrode layer 11c.

The vibration layer 11a may include a piezoelectric material or an electroactive material which has a piezoelectric effect. For example, the piezoelectric material may have a characteristic in which, when pressure or twisting phenomenon is applied to a crystalline structure by an external force, a potential difference occurs due to dielectric polarization caused by a relative position change of a positive (+) ion and a negative (−) ion, and a vibration is generated by an electric field based on a reverse voltage applied thereto. For example, the vibration layer 11a may be a piezoelectric layer, a piezoelectric material layer, an electroactive layer, a piezoelectric composite layer, a piezoelectric composite, or a piezoelectric ceramic composite, or the like, but embodiments of the present disclosure are not limited thereto.

The vibration layer 11a may be configured as a ceramic-based material for implementing a relatively strong vibration, or may be configured as a piezoelectric ceramic having a perovskite-based crystalline structure. The perovskite crystalline structure may have a piezoelectric effect and/or an inverse piezoelectric effect and may be a plate-shaped structure having orientation.

The piezoelectric ceramic may be configured as a single crystalline ceramic having a single crystalline structure, or may be configured as a ceramic material or polycrystalline ceramic having a polycrystalline structure. A piezoelectric material including the single crystalline ceramic may include α-AlPO₄, α-SiO₂, LiNbO₃, Tb₂(MoO₄)₃, Li₂B₄O₇, or ZnO, but embodiments of the present disclosure are not limited thereto. A piezoelectric material including the polycrystalline ceramic may include a lead zirconate titanate (PZT)-based material, including lead (Pb), zirconium (Zr), and titanium (Ti), or may include a lead zirconate nickel niobate (PZNN)-based material, including lead (Pb), zirconium (Zr), nickel (Ni), and niobium (Nb), but embodiments of the present disclosure are not limited thereto. For example, the vibration layer 11a may include at least one or more of calcium titanate (CaTiO₃), barium titanate (BaTiO₃), and strontium titanate (SrTiO₃), without lead (Pb), but embodiments of the present disclosure are not limited thereto.

The first electrode layer 11b may be disposed at a first surface (or an upper surface or a front surface) 11s1 of the vibration layer 11a. The first electrode layer 11b may have a same size as that of the vibration layer 11a, or may have a size which is smaller than that of the vibration layer 11a. For example, the first electrode layer 11b may have a same shape as that of the vibration layer 11a, but embodiments of the present disclosure are not limited thereto.

The second electrode layer 11c may be disposed at a second surface (or a lower surface or a rear surface) 11s2 which is opposite to or different from the first surface 11s1 of the vibration layer 11a. The second electrode layer 11c may have a same size as that of the vibration layer 11a, or may have a size which is smaller than that of the vibration layer 11a. For example, the second electrode layer 11c may have a same shape as that of the vibration layer 11a, but embodiments of the present disclosure are not limited thereto.

According to an embodiment of the present disclosure, one or more of the first electrode layer 11b and the second electrode layer 11c may be formed of a transparent conductive material, a semitransparent conductive material, or an opaque conductive material. For example, the transparent conductive material or the semitransparent conductive material may include indium tin oxide (ITO) or indium zinc oxide (IZO), but embodiments of the present disclosure are not limited thereto. The opaque conductive material may include gold (Au), silver (Ag), platinum (Pt), palladium (Pd), molybdenum (Mo), magnesium (Mg), carbon, or silver (Ag) including glass frit, or the like, or may be formed of an alloy thereof, but embodiments of the present disclosure are not limited thereto. Additionally, to enhance an electrical characteristic and/or a vibration characteristic of the vibration layer 11a, each of the first electrode layer 11b and the second electrode layer 11c may include silver (Ag) having a low resistivity. In addition, carbon may be carbon black, ketjen black, carbon nanotube, and a carbon material including graphite, but embodiments of the present disclosure are not limited thereto.

The vibration layer 11a may be polarized (or poling) by a certain voltage applied to the first electrode layer 11b and the second electrode layer 11c in a certain temperature atmosphere, or a temperature atmosphere that may be changed from a high temperature to a room temperature, but embodiments of the present disclosure are not limited thereto. For example, a polarization direction (or a poling direction) formed in the vibration layer 11a may be formed or aligned (or arranged) from the first electrode layer 11b to the second electrode layer 11c, but is not limited thereto, and a polarization direction (or a poling direction) formed in the vibration layer 11a may be formed or aligned (or arranged) from the second electrode layer 11c to the first electrode layer 11b.

The vibration layer 11a may alternately and repeatedly contract and/or expand based on an inverse piezoelectric effect according to a piezoelectric driving signal applied to the first electrode layer 11b and the second electrode layer 11c from an outside to vibrate. For example, the vibration layer 11a may vibrate in a vertical direction (or a thickness direction) and in a planar direction by the piezoelectric driving signal applied to the first electrode layer 11b and the second electrode layer 11c. The vibration layer 11a may be displaced (or vibrated or driven) by contraction and/or expansion of the planar direction, thereby improving a sound characteristic and/or a sound pressure level characteristic of the vibration apparatus 10.

The vibration apparatus 10 according to an embodiment of the present disclosure may further include a cover member 13.

The cover member 13 may be configured to cover at least one or more of a first surface and a second surface of the vibration part 11. The cover member 13 may be configured to protect at least one or more of the first surface and the second surface of the vibration part 11. For example, the first surface of the vibration part 11 may be a front surface or an upper surface. For example, the second surface of the vibration part 11 may be a rear surface or a lower surface which are opposite to the first surface.

The cover member 13 according to an embodiment of the present disclosure may include a first cover member 13a.

The first cover member 13a may be disposed at the first surface of the vibration part 11. For example, the first cover member 13a may be configured to cover the first electrode layer 11b of the vibration part 11. For example, the first cover member 13a may be configured to have a larger size than the vibration part 11. The first cover member 13a may be configured to protect the first surface of the vibration part 11 and the first electrode layer 11b.

The first cover member 13a according to an embodiment of the present disclosure may include an adhesive layer. For example, the first cover member 13a may include a base film, and an adhesive layer which is in the base film and is connected or coupled to the first surface of the vibration part 11. For example, the adhesive layer may include an electrical insulating material which has adhesive properties and is capable of compression and decompression, but embodiments of the present disclosure are not limited thereto.

The first cover member 13a according to another embodiment of the present disclosure may be connected or coupled to the first surface of the vibration part 11 by a first adhesive layer 13b. For example, the first cover member 13a may be connected or coupled to the first surface or the first electrode layer 11b of the vibration part 11 by the first adhesive layer 13b. For example, the first cover member 13a may be connected or coupled to the first surface or the first electrode layer 11b of the vibration part 11 by a film laminating process by the first adhesive layer 13b. The first adhesive layer 13b may be configured to surround an entire first surface or a portion of a lateral surface of the vibration part 11.

The cover member 13 according to an embodiment of the present disclosure may include a second adhesive layer 13c.

The second adhesive layer 13c may be disposed at the second surface of the vibration part 11. For example, the second adhesive layer 13c may be configured to cover the second electrode layer 11c of the vibration part 11. The second adhesive layer 13c may be configured to protect the second surface and the second electrode layer 11c of the vibration part 11. The second adhesive layer 13c may be configured to surround an entire second surface or a portion of a lateral surface of the vibration part 11. For example, the second adhesive layer 13c may be a protection layer or a protection member, but embodiments of the present disclosure are not limited thereto.

The second adhesive layer 13c may be connected or coupled to the first adhesive layer 13b in the lateral surface of the vibration part 11 or a periphery portion of the first cover member 13a. Thus, the first adhesive layer 13b and the second adhesive layer 13c may be configured to surround or completely surround the vibration part 11. The first adhesive layer 13b and the second adhesive layer 13c may be configured to cover or surround all surfaces of the vibration part 11. For example, the vibration part 11 may be inserted (or accommodated) or embedded (or built-in) at an inner portion of the adhesive layer including the first adhesive layer 13b and the second adhesive layer 13c.

The cover member 13 according to an embodiment of the present disclosure may further include a second cover member 13d, but embodiments of the present disclosure are not limited thereto.

The second cover member 13d may be disposed at the second surface of the vibration part 11. For example, the second cover member 13d may be configured to cover the second electrode layer 11c of the vibration part 11. For example, the second cover member 13d may be configured to have a larger size than the vibration part 11 and may be configured to have a same size as the first cover member 13a, but embodiments of the present disclosure are not limited thereto. The second cover member 13d may be configured to protect the second surface and the second electrode layer 11c of the vibration part 11.

The first cover member 13a and the second cover member 13d according to an embodiment of the present disclosure may include a same material or a different material. For example, each of the first cover member 13a and the second cover member 13d may be a polyimide film, a polyethylene naphthalate film, or a polyethylene terephthalate film, but embodiments of the present disclosure are not limited thereto.

The second cover member 13d may be connected or coupled to the second surface or the second electrode layer 11c of the vibration part 11 by using the second adhesive layer 13c. For example, the second cover member 13d may be connected or coupled to the second surface or the second electrode layer 11c of the vibration part 11 by a film laminating process by the second adhesive layer 13c.

The vibration part 11 may be disposed or inserted (or accommodated) between the first cover member 13a and the second cover member 13d. For example, the vibration part 11 may be inserted (or accommodated) or embedded (or built-in) at an inner portion of the adhesive layer including the first adhesive layer 13b and the second adhesive layer 13c, but embodiments of the present disclosure are not limited thereto.

Each of the first adhesive layer 13b and the second adhesive layer 13c according to an embodiment of the present disclosure may include an electrical insulating material which has adhesive properties and is capable of compression and decompression. For example, each of the first adhesive layer 13b and the second adhesive layer 13c may include epoxy resin, acrylic resin, silicone resin, urethane resin, a pressure sensitive adhesive (PSA), an optically cleared adhesive (OCA), or an optically cleared resin (OCR), or the like, but embodiments of the present disclosure are not limited thereto.

The first adhesive layer 13b and the second adhesive layer 13c may be configured between the first cover member 13a and the second cover member 13d to surround the vibration part 11. For example, one or more of the first adhesive layer 13b and the second adhesive layer 13c may be configured to surround the vibration part 11.

The vibration apparatus 10 according to an embodiment of the present disclosure may further include a signal supply member 17.

The signal supply member 17 may be configured to supply a piezoelectric driving signal supplied from a driving circuit part to the vibration part 11. The signal supply member 17 may be configured to be electrically connected to the vibration part 11. The signal supply member 17 may be configured to be electrically connected to the first electrode layer 11b and the second electrode layer 11c of the vibration part 11.

A portion of the signal supply member 17 may be accommodated (or inserted) between the cover member 13 and the vibration part 11. For example, the portion of the signal supply member 17 may be accommodated (or inserted) between the first surface of the vibration part 11 and the first cover member 13a. For example, the portion of the signal supply member 17 may be accommodated (or inserted) between the first cover member 13a and the second cover member 13d.

According to an embodiment of the present disclosure, an end portion (or a distal end portion or one side) of the signal supply member 17 may be disposed or inserted (or accommodated) between one periphery portion of the cover member 13 and the vibration part 11. For example, the end portion of the signal supply member 17 may be disposed or inserted (or accommodated) between one periphery portion of the first cover member 13a and the first surface of the vibration part 11. For example, the signal supply member 17 may be configured as a signal cable, a flexible cable, a flexible printed circuit cable, a flexible flat cable, a single-sided flexible printed circuit, a single-sided flexible printed circuit board, a flexible multilayer printed circuit, or a flexible multilayer printed circuit board, but embodiments of the present disclosure are not limited thereto.

The signal supply member 17 according to an embodiment of the present disclosure may include a base member 17a and a plurality of signal lines 17b and 17c. For example, the signal supply member 17 may include a base member 17a, a first signal line 17b, and a second signal line 17c.

The base member 17a may include a transparent or opaque plastic material, but embodiments of the present disclosure are not limited thereto.

The first and second signal lines 17b and 17c may be disposed at a first surface of the base member 17a and may be spaced apart from each other or electrically separated from each other. The first and second signal lines 17b and 17c may be disposed in parallel to each other at the first surface of the base member 17a. For example, the first and second signal lines 17b and 17c may be implemented in a line shape by patterning of a metal layer (or a conductive layer) formed or deposited at the first surface of the base member 17a.

End portions (or distal end portions or one sides) of the first and second signal lines 17b and 17c may be separated from each other, and thus, may be individually curved or bent.

The end portion of the first signal line 17b may be electrically connected to the first electrode layer 11b of the vibration part 11. For example, the end portion of the first signal line 17b may be electrically connected to at least a portion of the first electrode layer 11b of the vibration part 11 in the one periphery portion of the first cover member 13a. For example, the end portion of the first signal line 17b may be electrically and directly connected to at least a portion of the first electrode layer 11b of the vibration part 11. For example, the end portion of the first signal line 17b may be electrically connected to or directly contact the first electrode layer 11b of the vibration part 11. For example, the end portion of the first signal line 17b may be electrically connected to the first electrode layer 11b through a conductive double-sided tape. Accordingly, the first signal line 17b may be configured to supply a first piezoelectric driving signal component, supplied from the driving circuit part, to the first electrode layer 11b of the vibration part 11.

The end portion of the second signal line 17c may be electrically connected to the second electrode layer 11c of the vibration part 11. For example, the end portion of the second signal line 17c may be electrically connected to at least a portion of the second electrode layer 11c of the vibration part 11 in one periphery portion of the second cover member 13d. For example, the end portion of the second signal line 17c may be electrically and directly connected to at least a portion of the second electrode layer 11c of the vibration part 11. For example, the end portion of the second signal line 17c may be electrically connected to or directly contact the second electrode layer 11c of the vibration part 11. For example, the end portion of the second signal line 17c may be electrically connected to the second electrode layer 11c through a conductive double-sided tape. Accordingly, the second signal line 17c may be configured to supply a second piezoelectric driving signal component, supplied from the driving circuit part, to the second electrode layer 11c of the vibration part 11. The first and second piezoelectric driving signal components constitutes the piezoelectric driving signal.

The signal supply member 17 according to an embodiment of the present disclosure may further include an insulation layer 17d.

The insulation layer 17d may be disposed at the first surface of the base member 17a to cover each of the first signal line 17b and the second signal line 17c other than the end portion (or one side) of the signal supply member 17.

According to an embodiment of the present disclosure, an end portion (or one side) of the signal supply member 17 including an end portion (or one side) of the base member 17a and an end portion (or one side) of the insulation layer 17d may be inserted (or accommodated) between the cover member 13 and the vibration part 11 and may be fixed between the cover member 13 (or first cover member 13a) and the vibration part 11 by the first adhesive layer 13b and the second adhesive layer 13c.

According to another embodiment of the present disclosure, an end portion (or one side) of the signal supply member 17 including an end portion of the base member 17a and an end portion of the insulation layer 17d may be inserted (or accommodated) between the first cover member 13a and the second cover member 13d and may be fixed between the first cover member 13a and the second cover member 13d by the first adhesive layer 13b and the second adhesive layer 13c. Accordingly, the end portion of the first signal line 17b may be maintained with being electrically connected to the first electrode layer 11b of the vibration part 11, and the end portion of the second signal line 17c may be maintained with being electrically connected to the second electrode layer 11c of the vibration part 11. In addition, the end portion of the signal supply member 17 may be inserted (or accommodated) and fixed between the vibration part 11 and the first cover member 13a, and thus, a contact defect between the vibration apparatus 10 and the signal supply member 17 caused by the movement of the signal supply member 17 may be prevented. Alternatively, the end portion of the signal supply member 17 may be inserted (or accommodated) and fixed between the vibration part 11 and the second cover member 13d.

In the signal supply member 17 according to an embodiment of the present disclosure, each of the end portion of the base member 17a and the end portion of the insulation layer 17d may be disposed from the corresponding end portions of the first and second signal lines 17b, 17c by a certain distance. For example, each of the end portion of the first signal line 17b and the end portion of the second signal line 17c may be exposed at the outside without being supported or covered by each of the end portion of the base member 17a and the end portion of the insulation layer 17d, respectively. For example, the end portion of each of the first signal line 17b and the second signal line 17c may protrude (or extend) to have a certain length from an end of the base member 17a or an end of the insulation layer 17d. Accordingly, each of the end portion of each of the first signal line 17b and the second signal line 17c may be individually or independently bent.

The end portion of the first signal line 17b, which is not supported by the end portion of the base member 17a and the end portion of the insulation layer 17d, may be directly connected to or directly contact the first electrode layer 11b of the vibration part 11. The end portion of the second signal line 17c, which is not supported by the end portion of the base member 17a and the end portion of the insulation layer 17d, may be directly connected to or directly contact the second electrode layer 11c of the vibration part 11.

According to an embodiment of the present disclosure, a portion of the signal supply member 17 or a portion of the base member 17a may be disposed or inserted (or accommodated) between the cover member 13 and the vibration part 11, and thus, the signal supply member 17 may be integrated as one body with the vibration part 11. Further, a portion of the signal supply member 17 or a portion of the base member 17a may be disposed or inserted (or accommodated) between the first cover member 13a and the second cover member 13d, and thus, the signal supply member 17 may be integrated as one body with the vibration apparatus 10. Accordingly, the vibration apparatus 10 and the signal supply member 17 may be configured as one part (or one element or one component), and thus, an effect of uni-materialization may be obtained.

According to an embodiment of the present disclosure, the first signal line 17b and the second signal line 17c of the signal supply member 17 may be integrated as one body with the vibration apparatus 10, and thus, a soldering process for an electrical connection between the vibration apparatus 10 and the signal supply member 17 is not be needed. Accordingly, a manufacturing process and a structure of the vibration apparatus 10 may be simplified, and hazards associated with the soldering process may be reduced.

FIG. 16 is a perspective view illustrating a vibration layer according to another embodiment of the present disclosure. For example, FIG. 16 illustrates another embodiment of the vibration layer described above with reference to FIGS. 13 to 15.

With reference to FIGS. 14 and 16, the vibration layer 11a according to another embodiment of the present disclosure may include a plurality of first portions 11a1 and a plurality of second portions 11a2. For example, the plurality of first portions 11a1 and the plurality of second portions 11a2 may be alternately and repeatedly disposed along a first direction X (or second direction Y).

Each of the plurality of first portions 11a1 may include an inorganic material portion having a piezoelectric effect (or a piezoelectric characteristic). For example, each of the plurality of first portions 11a1 may include at least one or more of a piezoelectric inorganic material and a piezoelectric organic material. For example, each of the plurality of first portions 11a1 may be an inorganic portion, an inorganic material portion, a piezoelectric portion, a piezoelectric material portion, or an electroactive portion, but embodiments of the present disclosure are not limited thereto.

According to an embodiment of the present disclosure, each of the plurality of first portions 11a1 may have a first width W1 parallel to the first direction X (or the second direction Y) and may be extended along the second direction Y (or the first direction X). Each of the plurality of first portions 11a1 may be substantially a same as a vibration layer 11a described above with reference to FIGS. 13 to 15, and thus, its repeated descriptions are omitted.

Each of the plurality of second portions 11a2 may be disposed between the plurality of first portions 11a1. For example, each of the plurality of first portions 11a1 may be disposed between two adjacent second portions 11a2 of the plurality of second portions 11a2. Each of the plurality of second portions 11a2 may have a second width W2 parallel to the first direction X (or the second direction Y) and may be extended along the second direction Y (or the first direction X). The first width W1 may be a same as or different from the second width W2. For example, the first width W1 may be greater than the second width W2. For example, the first portion 11a1 and the second portion 11a2 may include a line shape or a stripe shape which has a same size or different sizes, but embodiments of the present disclosure are not limited thereto.

Each of the plurality of second portions 11a2 may be configured to fill a gap between two adjacent first portions of the plurality of first portions 11a1. Each of the plurality of second portions 11a2 may be configured to fill a gap between two adjacent first portions of the plurality of first portions 11a1, and thus, may be connected to or attached at lateral surfaces of the first portion 11a1 adjacent thereto. According to an embodiment of the present disclosure, each of the plurality of first portions 11a1 and the plurality of second portions 11a2 may be disposed (or arranged) at a same plane (or a same layer) in parallel with each other. Therefore, the vibration layer 11a may be expanded to a desired size or length by a lateral coupling (or connection) of the first portions 11a1 and the second portions 11a2.

According to an embodiment of the present disclosure, each of the plurality of second portions 11a2 may absorb an impact applied to the first portions 11a1, and thus, may enhance the total durability of the first portions 11a1 and provide flexibility to the vibration layer 11a. Each of the plurality of second portions 11a2 may include an organic material having a ductile characteristic. For example, each of the plurality of second portions 11a2 may include one or more of an epoxy-based polymer, an acrylic-based polymer, and a silicone-based polymer, but embodiments of the present disclosure are not limited thereto. For example, each of the plurality of second portions 11a2 may be an organic portion, an organic material portion, an adhesive portion, a stretch portion, a bending portion, a damping portion, or a ductile portion, but embodiments of the present disclosure are not limited thereto.

A first surface of each of the plurality of first portions 11a1 and the plurality of second portions 11a2 may be connected to the first electrode layer 11b in common. A second surface of each of the plurality of first portions 11a1 and the plurality of second portions 11a2 may be connected to the second electrode layer 11c in common.

The plurality of first portions 11a1 and the plurality of second portion 11a2 may be disposed (or connected) at a same plane, and thus, the vibration part 11a according to another embodiment of the present disclosure may have a single thin film-type. Accordingly, the vibration layer 11 or the vibration apparatus 10 including the vibration layer 11a according to another embodiment of the present disclosure may vibrate by the first portion 11a1 having a vibration characteristic and may be bent in a curved shape by the second portion 11a2 having flexibility.

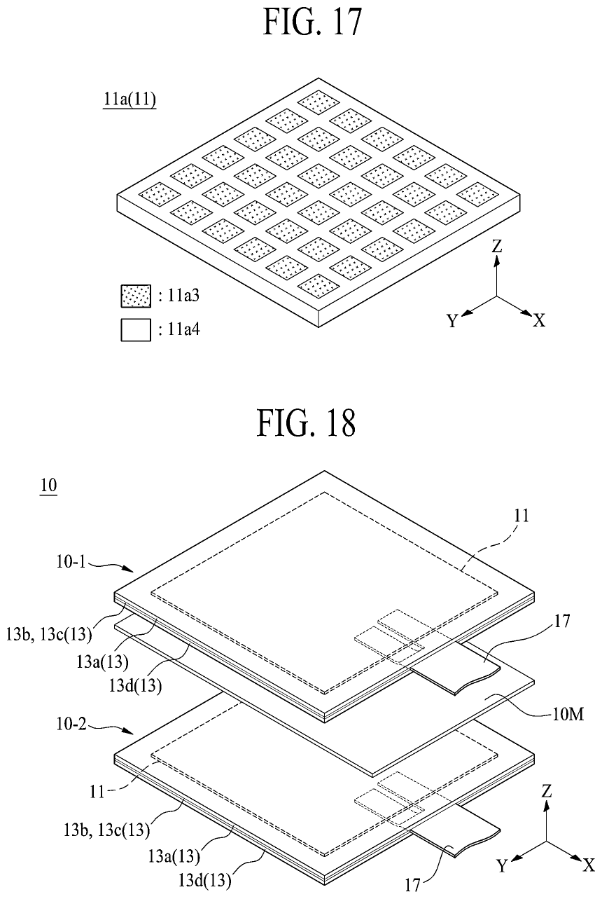

FIG. 17 is a perspective view illustrating a vibration layer according to another embodiment of the present disclosure. For example, FIG. 17 illustrates another embodiment of the vibration layer described above with reference to FIGS. 13 to 15.

With reference to FIGS. 14 and 17, the vibration layer 11a according to another embodiment of the present disclosure may include a plurality of first portions 11a3 and a second portion 11a4 disposed between the plurality of first portions 11a3.

Each of the plurality of first portions 11a3 may be disposed to be spaced apart from one another along each of the first direction X and the second direction Y. For example, each of the plurality of first portions 11a3 may have a hexahedral shape having a same size and may be disposed in a lattice shape, but embodiments of the present disclosure are not limited thereto. For example, each of the plurality of first portions 11a3 may have a circular shape plate, an oval shape plate, or a polygonal shape plate, which has a same size as each other, but embodiments of the present disclosure are not limited thereto.

Each of the plurality of first portions 11a3 may be substantially a same as the first portion 11a1 described above with reference to FIG. 16, and thus, its repeated descriptions are omitted.

The second portion 11a4 may be disposed between the plurality of first portions 11a3 along each of the first direction X and the second direction Y. The second portion 11a4 may be configured to fill a gap between two adjacent first portions 11a3, or to be adjacent to each of the plurality of first portions 11a3 or to surround each of the plurality of first portions 11a3, and thus, the second portion 11a4 may be connected to or attached at the first portion 11a3 adjacent thereto. The second portion 11a4 may be substantially a same as the second portion 11a2 described above with reference to FIG. 16, and thus, its repeated descriptions are omitted.

A first surface of each of the plurality of first portions 11a3 and the second portions 11a4 may be connected to the first electrode layer 11b in common. A second surface of each of the plurality of first portions 11a3 and the second portions 11a4 may be connected to the second electrode layer 11c in common.

The plurality of first portions 11a3 and the second portion 11a4 may be disposed (or connected) at a same plane, and thus, the vibration layer 11a according to another embodiment of the present disclosure may have a single thin film-type, but embodiments of the present disclosure are not limited thereto. Accordingly, the vibration part 11 of the vibration apparatus 10 including the vibration layer 11a according to another embodiment of the present disclosure may vibrate by the first portion 11a3 having a vibration characteristic and may be bent in a curved shape by the second portion 11a4 having flexibility.

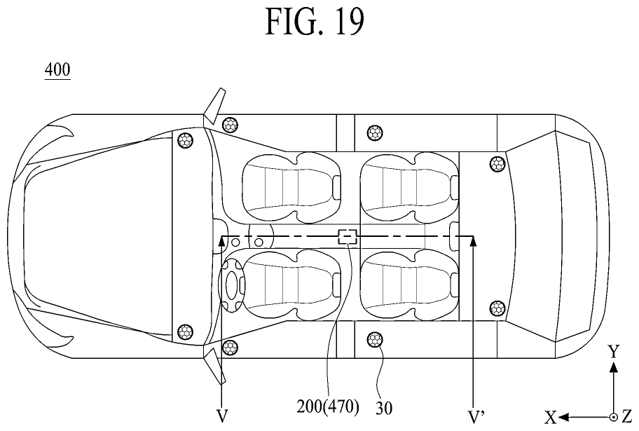

FIG. 18 is an exploded perspective view illustrating a vibration apparatus according to another embodiment of the present disclosure. For example, FIG. 18 illustrates a vibration apparatus described above with reference to FIGS. 1 to 12.

With reference to FIG. 18, the vibration apparatus 10 according to another embodiment of the present disclosure can include two or more vibration generating parts 10-1 and 10-2. For example, the vibration apparatus 10 may include a first vibration generating part 10-1 and a second vibration generating part 10-2.

The first vibration generating part 10-1 and the second vibration generating part 10-2 may overlap or be stacked with each other to be displaced (or driven or vibrated) in a same direction to maximize an amplitude displacement of the vibration apparatus 10 or an amplitude displacement of the vibration member. For example, the first vibration generating part 10-1 and the second vibration generating part 10-2 may have substantially a same size, but embodiments of the present disclosure are not limited thereto. For example, the first vibration generating part 10-1 and the second vibration generating part 10-2 may have substantially a same size within an error range of a manufacturing process, but embodiments of the present disclosure are not limited thereto. Therefore, the first vibration generating part 10-1 and the second vibration generating part 10-2 may maximize the amplitude displacement of the vibration apparatus 10 and/or the amplitude displacement of the vibration member.

Each of the first vibration generating part 10-1 and the second vibration generating part 10-2 may be a same as or substantially a same as the vibration apparatus 10 described above with reference to FIGS. 13 to 17, and thus, like reference numeral refer to like element and its repeated descriptions are omitted.

The vibration apparatus 10 according to another embodiment of the present disclosure may further include an intermediate adhesive member 10M.

The intermediate adhesive member 10M may be disposed or connected between the first vibration generating part 10-1 and the second vibration generating part 10-2. As an embodiment of the present disclosure, the intermediate adhesive member 10M may be disposed or connected between the second adhesive layer 13c of the first vibration generating part 10-1 and the first cover member 13a of the second vibration generating part 10-2. As another embodiment of the present disclosure, the intermediate adhesive member 10M may be disposed or connected between the second cover member 13d of the first vibration generating part 10-1 and the first cover member 13a of the second vibration generating part 10-2. For example, the intermediate adhesive member 10M may be an intermediate member, an adhesive member, or a connection member, but embodiments of the present disclosure are not limited thereto.

The intermediate adhesive member 10M according to an embodiment of the present disclosure may be configured in a material including an adhesive layer which is good in adhesive force or attaching force with respect to each of the first vibration generating part 10-1 and the second vibration generating part 10-2, but embodiments of the present disclosure are not limited thereto. For example, the intermediate adhesive member 10M may include a foam pad, a double-sided tape, a double-sided foam tape, a double-sided foam pad, a double-sided adhesive tape, or an adhesive, or the like, but embodiments of the present disclosure are not limited thereto. For example, an adhesive layer of the intermediate adhesive member 10M may include epoxy, acrylic, silicone, or urethane, but embodiments of the present disclosure are not limited thereto. For example, the adhesive layer of the intermediate adhesive member 10M may include a urethane-based material (or substance) having relatively ductile characteristic. Accordingly, the vibration loss caused by displacement interference between the first vibration generating part 10-1 and the second vibration generating part 10-2 may be reduced or minimized, or each of the first vibration generating part 10-1 and the second vibration generating part 10-2 may be freely displaced (or vibrated or driven).

The vibration apparatus 10 according to another embodiment of the present disclosure may include the first vibration generating part 10-1 and the second vibration generating part 10-2 which are stacked (or piled or overlap) to vibrate (or displace or drive) in a same direction, and thus, the amount of displacement or an amplitude displacement may be maximized or increase. Accordingly, the amount of displacement (or a bending force or a driving force) or an amplitude displacement of the vibration member may be more maximized or more increased, thereby more enhancing a sound characteristic and/or a sound pressure level characteristic of a low-pitched sound band.

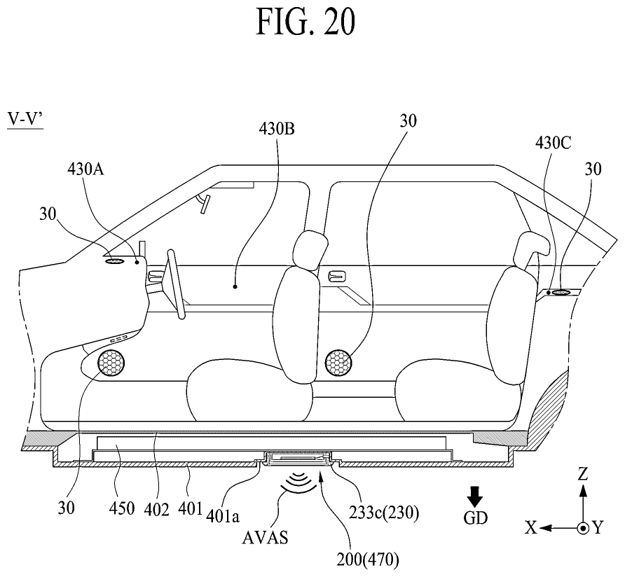

FIG. 19 is a plan view illustrating a vehicular apparatus according to another embodiment of the present disclosure. FIG. 20 is a cross-sectional view taken along line V-V′ illustrated in FIG. 19 according to an embodiment of the present disclosure.

With reference to FIGS. 19 and 20, the vehicular apparatus 400 according to an embodiment of the present disclosure may include a vehicle body bottom 401, a battery module 450, and one or more virtual engine sound apparatuses 470.

The vehicle body bottom (or vehicle body floor) 401 may be a structure of the vehicular apparatus 400. The vehicle body bottom 401 may be configured to support or cover a vehicle body lower frame 402. For example, the vehicle body bottom 401 may be a vehicle body panel or a vehicle body frame, but embodiments of the present disclosure are not limited thereto.

The battery module 450 may be disposed at or mount on a vehicle body bottom frame 402. For example, the battery module 450 may be disposed between the vehicle body bottom frame 402 and the vehicle body bottom 401. For example, the battery module 450 may be disposed to be covered by the vehicle body bottom 401.

The one or more virtual engine sound apparatuses 470 may be an apparatus (or a device) for transferring a location and/or driving information of the vehicular apparatus 400 to a pedestrian. For example, the one or more virtual engine sound apparatuses 470 may be a virtual engine sound system or a vehicle access information apparatus, but embodiments of the present disclosure are not limited thereto.

The one or more virtual engine sound apparatuses 470 may include the sound apparatus 200 described above with reference to FIGS. 6 to 8, and thus, its repeated descriptions are omitted. For example, the one or more virtual engine sound apparatuses 470 may be configured to output a sound or a virtual engine sound AVAS of 150 Hz to 20 kHz.

The one or more virtual engine sound apparatuses 470 or the supporting member 230 of the sound apparatus 200 according to an embodiment of the present disclosure may be disposed in (or mounted on) a region between the battery module 450 and the vehicle body bottom 401 or a region between the vehicle body bottom frame 402 and the vehicle body bottom 401. For example, the one or more virtual engine sound apparatuses 470 may be configured to be covered by the vehicle body bottom 401. For example, a portion of the vehicle body bottom 401 overlapping the one or more virtual engine sound apparatuses 470 may include one or more holes for outputting a sound (or a virtual engine sound) AVAS, output from the one or more virtual engine sound apparatuses 470, in an earth-surface direction (or a ground direction) GD.

The one or more virtual engine sound apparatuses 470 according to another embodiment of the present disclosure may be accommodated (or received) into the vehicle body bottom 401. The vehicle body bottom 401 may include an accommodating part 401a for accommodating (or receiving) the one or more virtual engine sound apparatuses 470. For example, the accommodating part 401a of the vehicle body bottom 401 may protrude toward the battery module 450 from the vehicle body bottom 401 to include an accommodating space.

The one or more virtual engine sound apparatuses 470 according to another embodiment of the present disclosure may be accommodated (or received) into the accommodating part 401a of the vehicle body bottom 401 by a plurality of fastening members and may be fixed to (or mounted on) the vehicle body bottom 401. For example, the supporting member 230 of the sound apparatus 200 configured in the one or more virtual engine sound apparatuses 470 may be accommodated (or received) into the accommodating part 401a of the vehicle body bottom 401. For example, the protrusion part 233c of the supporting member 230 may be in contact with the vehicle body bottom 401 in a periphery of the accommodating part 401a of the vehicle body bottom 401. Accordingly, one or more virtual engine sound apparatuses 470 may be fixed to (or mounted on) the vehicle body bottom 401 and output the sound (or virtual engine sound) AVAS toward the earth-surface direction GD.

The one or more virtual engine sound apparatuses 470 may include the piezoelectric-type vibration apparatus 10, and thus, may be lightweight and may have a thin thickness, and may output a sound (or a virtual engine sound) AVAS having a wide directivity angle or a non-directivity angle, based on a non-directivity characteristic of the vibration apparatus 10. The one or more virtual engine sound apparatuses 470 according to an embodiment of the present disclosure may output a sound (or a virtual engine sound) AVAS having a wide directivity angle compared to a sound generated based on a vibration of an actuator including a magnet and a coil. For example, in a case where the one or more virtual engine sound apparatuses 470 are disposed (or configured) corresponding to a center of the vehicular apparatus 400 or the vehicle body bottom 401 to output a virtual engine sound AVAS, the one or more virtual engine sound apparatuses 470 may output a uniform virtual engine sound AVAS in (toward) each of a forward direction, a rearward direction, a left direction, and a right direction with respect to the center of the vehicular apparatus 400 or the vehicle body bottom 401. The one or more virtual engine sound apparatuses 470 according to an embodiment of the present disclosure may output a sound or a virtual engine sound AVAS having a sound pressure level of 60 dB or more in a pitched sound band of 300 Hz or more, but embodiments of the present disclosure are not limited thereto.

The vehicular apparatus 400 according to an embodiment of the present disclosure may further include one or more actuators 30.

The one or more actuators 30 may be disposed at one or more of a dashboard 430A, a door frame 430B, and a rear package interior material 430C, but embodiments of the present disclosure are not limited thereto. For example, one or more actuators 30 may be disposed at one or more of a pillar interior material, a roof interior material, a door interior material, a seat interior material, a handle interior material, and a floor interior material, but embodiments of the present disclosure are not limited thereto.

The one or more actuators 30 may include a magnet and a coil. The one or more actuators 30 may be one or more of a woofer, a mid-woofer, and a sub-woofer, but embodiments of the present disclosure are not limited thereto. For example, the one or more actuators 30 may be a speaker which outputs a sound of about 30 Hz to about 150 Hz, or about 300 Hz or less, but embodiments of the present disclosure are not limited thereto. Therefore, the one or more actuators 30 may output a sound of about 30 Hz to about 150 Hz, or about 300 Hz or less, and thus, may enhance a low-pitched sound band characteristic of a sound which is output to an interior space.

The one or more actuators 30 may drive (or vibrate) based on the actuator driving signals applied through the signal supply member 17 from the sound driving circuit 101 of the driving circuit part 100 in the sound apparatus described above with reference to FIGS. 4 and 5, to generate (or output) a sound.

According to an embodiment of the present disclosure, the sound driving circuit 101 of the driving circuit part 100 may drive (or vibrate) the one or more virtual engine sound apparatuses 470 and the one or more actuators 30, respectively, but embodiments of the present disclosure are not limited thereto.

A sound driving circuit, a sound apparatus comprising the same, and a vehicular apparatus comprising the sound apparatus according to one or more embodiments of the present disclosure will be described below.

A sound driving circuit according to one or more embodiments of the present disclosure may comprise an audio processor generating an input audio signal based on a sound source, a signal conversion circuit converting the input audio signal into a piezoelectric audio signal, and an amplifier circuit amplifying the piezoelectric audio signal to generate a piezoelectric driving signal for driving a vibration apparatus of a piezoelectric-type.

According to one or more embodiments of the present disclosure, the signal conversion circuit may comprise a filter circuit attenuating a high-pitched sound band signal of the input audio signal to generate the piezoelectric driving signal.

According to one or more embodiments of the present disclosure, the high-pitched sound band signal may have a frequency of 1 kHz or more.

According to one or more embodiments of the present disclosure, the signal conversion circuit further may comprise a correction circuit increasing a first pitched sound band signal of the input audio signal and/or decreasing a second pitched sound band signal differing from the first pitched sound band signal to generate a first audio correction signal, a level control circuit controlling a volume level of the first audio correction signal to generate a second audio correction signal, and a clipping circuit removing noise of the second audio correction signal to generate a third audio correction signal. The filter circuit may attenuate the high-pitched sound band signal of the third audio correction signal to generate the piezoelectric driving signal.

According to one or more embodiments of the present disclosure, the first pitched sound band signal may have a frequency of 250 Hz to 600 Hz. The second pitched sound band signal may have a frequency of 1 kHz or more.

According to one or more embodiments of the present disclosure, the correction circuit may include a first correction circuit for increasing the first pitched sound band signal, a second correction circuit for decreasing the second pitched sound band signal, and a mixing circuit for mixing the increased first pitched sound band signal and the decreased second pitched sound band signal to generate the first audio correction signal.

A sound driving circuit according to one or more embodiments of the present disclosure may comprise an audio processor generating an audio signal based on a sound source, a preamplifier circuit amplifying the audio signal to generate an input audio signal, a signal conversion circuit converting the input audio signal into a piezoelectric audio signal, and an amplifier circuit amplifying the piezoelectric audio signal to generate a piezoelectric driving signal for driving a vibration apparatus of a piezoelectric-type.

According to one or more embodiments of the present disclosure, the signal conversion circuit may comprise a filter circuit attenuating a high-pitched sound band signal of the input audio signal to generate the piezoelectric driving signal.

According to one or more embodiments of the present disclosure, the high-pitched sound band signal may have a frequency of 1 kHz or more.

According to one or more embodiments of the present disclosure, the signal conversion circuit further may comprise a correction circuit increasing a first pitched sound band signal of the input audio signal and/or decreasing a second pitched sound band signal differing from the first pitched sound band signal to generate a first audio correction signal, a level control circuit controlling a volume level of the first audio correction signal to generate a second audio correction signal, and a clipping circuit removing noise of the second audio correction signal to generate a third audio correction signal. The filter circuit may attenuate the high-pitched sound band signal of the third audio correction signal to generate the piezoelectric driving signal.

According to one or more embodiments of the present disclosure, the first pitched sound band signal may have a frequency of 250 Hz to 600 Hz. The second pitched sound band signal may have a frequency of 1 kHz or more.

According to one or more embodiments of the present disclosure, the correction circuit may include a first correction circuit for increasing the first pitched sound band signal, a second correction circuit for decreasing the second pitched sound band signal, and a mixing circuit for mixing the increased first pitched sound band signal and the decreased second pitched sound band signal to generate the first audio correction signal.

A sound driving circuit according to one or more embodiments of the present disclosure may comprise an audio processor generating a first input audio signal and one or more second input audio signals based on a sound source, a signal conversion circuit converting the first input audio signal into a piezoelectric audio signal, and an amplifier circuit amplifying the one or more second input audio signals to generate one or more actuator driving signals for driving one or more actuators of a coil-type and amplifying the piezoelectric audio signal to generate a piezoelectric driving signal for driving a vibration apparatus of a piezoelectric-type.

According to one or more embodiments of the present disclosure, the signal conversion circuit may comprise a filter circuit attenuating a high-pitched sound band signal of the first input audio signal to generate the piezoelectric driving signal.

According to one or more embodiments of the present disclosure, the high-pitched sound band signal may have a frequency of 1 kHz or more.

According to one or more embodiments of the present disclosure, the signal conversion circuit further may comprise a correction circuit increasing a first pitched sound band signal of the first input audio signal and/or decreasing a second pitched sound band signal differing from the first pitched sound band signal to generate a first audio correction signal, a level control circuit controlling a volume level of the first audio correction signal to generate a second audio correction signal, and a clipping circuit removing noise of the second audio correction signal to generate a third audio correction signal. The filter circuit may attenuate the high-pitched sound band signal of the third audio correction signal to generate the piezoelectric driving signal.

According to one or more embodiments of the present disclosure, the first pitched sound band signal may have a frequency of 250 Hz to 600 Hz. The second pitched sound band signal may have a frequency of 1 kHz or more.

According to one or more embodiments of the present disclosure, the correction circuit may include a first correction circuit for increasing the first pitched sound band signal, a second correction circuit for decreasing the second pitched sound band signal, and a mixing circuit for mixing the increased first pitched sound band signal and the decreased second pitched sound band signal to generate the first audio correction signal.

A sound driving circuit according to one or more embodiments of the present disclosure may comprise an audio processor generating a first audio signal and one or more second audio signals based on a sound source, a preamplifier circuit amplifying the one or more second audio signals to generate the one or more second input audio signals and amplifying the first audio signal to generate the first input audio signal, a signal conversion circuit converting the first input audio signal into a piezoelectric audio signal, and an amplifier circuit amplifying the one or more second input audio signals to generate one or more actuator driving signals for driving one or more actuators of a coil-type and amplifying the piezoelectric audio signal to generate a piezoelectric driving signal for driving a vibration apparatus of a piezoelectric-type.

According to one or more embodiments of the present disclosure, the signal conversion circuit may comprise a filter circuit attenuating a high-pitched sound band signal of the first input audio signal to generate the piezoelectric driving signal.

According to one or more embodiments of the present disclosure, the high-pitched sound band signal may have a frequency of 1 kHz or more.

According to one or more embodiments of the present disclosure, the signal conversion circuit further may comprise a correction circuit increasing a first pitched sound band signal of the first input audio signal and/or decreasing a second pitched sound band signal differing from the first pitched sound band signal to generate a first audio correction signal, a level control circuit controlling a volume level of the first audio correction signal to generate a second audio correction signal, and a clipping circuit removing noise of the second audio correction signal to generate a third audio correction signal. The filter circuit may attenuate the high-pitched sound band signal of the third audio correction signal to generate the piezoelectric driving signal.

According to one or more embodiments of the present disclosure, the first pitched sound band signal may have a frequency of 250 Hz to 600 Hz. The second pitched sound band signal may have a frequency of 1 kHz or more.

According to one or more embodiments of the present disclosure, the correction circuit may include a first correction circuit for increasing the first pitched sound band signal, a second correction circuit for decreasing the second pitched sound band signal, and a mixing circuit for mixing the increased first pitched sound band signal and the decreased second pitched sound band signal to generate the first audio correction signal.

A sound apparatus according to one or more embodiments of the present disclosure may comprise a vibration apparatus including a piezoelectric material, and a driving circuit part connected to the vibration apparatus. The driving circuit part comprises a sound driving circuit applying the piezoelectric driving signal to the vibration apparatus, as previously described.

According to one or more embodiments of the present disclosure, the vibration apparatus may comprise a vibration part including the piezoelectric material, a cover member covering at least one or more of a first surface of the vibration part and a second surface of the vibration part opposite to the first surface, and a signal supply member electrically connected to the vibration part and connected to the driving circuit part.

According to one or more embodiments of the present disclosure, the sound apparatus may further comprise a passive vibration member. The vibration apparatus may be disposed to vibrate the passive vibration member.

According to one or more embodiments of the present disclosure, the passive vibration member may comprise any one of a display panel including a pixel configured to display an image, a screen panel on which an image is to be projected from a display apparatus, a lighting panel, a signage panel, a vehicular interior material, a vehicular exterior material, a vehicular glass window, a vehicular seat interior material, a vehicular ceiling material, a building ceiling material, a building interior material, a building glass window, an aircraft interior material, an aircraft glass window, and a mirror.

According to one or more embodiments of the present disclosure, the sound apparatus may further comprise a vibration member, and a supporting member having an internal space and configured at a periphery of the vibration member. The vibration apparatus may be in the internal space of the supporting member and is disposed to vibrate the vibration member.

A sound apparatus according to one or more embodiments of the present disclosure may comprise a vibration apparatus including a piezoelectric material, one or more actuators including a magnet and a coil, and a driving circuit part connected to the vibration apparatus and the one or more actuators. The driving circuit part may comprise a sound driving circuit. The sound driving circuit may apply the piezoelectric driving signal to the vibration apparatus and may apply the one or more actuator driving signals to the one or more actuators, as previously described.

According to one or more embodiments of the present disclosure, the vibration apparatus may comprise a vibration part including the piezoelectric material, a cover member covering at least one or more of a first surface of the vibration part and a second surface of the vibration part opposite to the first surface, and a signal supply member electrically connected to the vibration part and connected to the driving circuit part.

A vehicular apparatus according to one or more embodiments of the present disclosure may comprise an exterior material, an interior material covering the exterior material, and one or more sound generating apparatuses configured to output a sound in one or more of the exterior material, the interior material, and a region between the exterior material and the interior material. The one or more sound generating apparatuses may comprise a sound apparatus, as previously described.

According to one or more embodiments of the present disclosure, the vehicular apparatus may further comprise a vibration member, and a supporting member having an internal space and supporting the vibration member. The vibration apparatus of the sound apparatus may be in the internal space of the supporting member and may be disposed to vibrate the vibration member.

According to one or more embodiments of the present disclosure, the vibration apparatus of the sound apparatus may comprise a vibration part including the piezoelectric material, a cover member covering at least one or more of a first surface of the vibration part and a second surface of the vibration part opposite to the first surface, and a signal supply member electrically connected to the vibration part and connected to the driving circuit part.

According to one or more embodiments of the present disclosure, a portion of the signal supply member may be accommodated between the cover member and the vibration part.

According to one or more embodiments of the present disclosure, the interior material may comprise at least one or more of a dash board, a pillar interior material, a roof interior material, a door interior material, a seat interior material, a handle interior material, a floor interior material, and a rear package interior material.

According to one or more embodiments of the present disclosure, the exterior material may comprise at least one or more of a hood panel, a front fender panel, a door panel, a roof panel, a pillar panel, a trunk panel, a front bumper, a rear bumper, a spoiler, a headlight, a taillight, a fog light, and a vehicle body bottom.

A vehicular apparatus according to one or more embodiments of the present disclosure may comprise an exterior material, an interior material covering the exterior material, and one or more sound generating apparatuses configured to output a sound in one or more of the exterior material, the interior material, and a region between the exterior material and the interior material. the one or more sound generating apparatuses may comprise a sound apparatus, as previously described.

According to one or more embodiments of the present disclosure, the vibration apparatus of the sound apparatus may comprise a vibration part including the piezoelectric material, a cover member covering at least one or more of a first surface of the vibration part and a second surface of the vibration part opposite to the first surface, and a signal supply member electrically connected to the vibration part and connected to the driving circuit part.

According to one or more embodiments of the present disclosure, a portion of the signal supply member may be accommodated between the cover member and the vibration part.

According to one or more embodiments of the present disclosure, the interior material may comprise at least one or more of a dash board, a pillar interior material, a roof interior material, a door interior material, a seat interior material, a handle interior material, a floor interior material, and a rear package interior material.

According to one or more embodiments of the present disclosure, the exterior material may comprise at least one or more of a hood panel, a front fender panel, a door panel, a roof panel, a pillar panel, a trunk panel, a front bumper, a rear bumper, a spoiler, a headlight, a taillight, a fog light, and a vehicle body bottom.

According to one or more embodiments of the present disclosure, the one or more actuators of the sound apparatus may be disposed at one or more of a dash board, a door frame, a rear package interior material, a pillar interior material, a roof interior material, a door interior material, a seat interior material, a handle interior material, and a floor interior material.

A vehicular apparatus according to one or more embodiments of the present disclosure may comprise a vehicle body bottom frame, and a vehicle body bottom covering the vehicle body bottom frame, and one or more virtual engine sound apparatuses mounted on the vehicle body bottom or a region between the vehicle body bottom frame and the vehicle body bottom. The one or more virtual engine sound apparatuses comprise a sound apparatus, as previously described.

According to one or more embodiments of the present disclosure, the one or more virtual engine sound apparatuses may be disposed to correspond to a center of the vehicle body bottom.

According to one or more embodiments of the present disclosure, the vibration apparatus of the sound apparatus may comprise a vibration part including the piezoelectric material, a cover member covering at least one or more of a first surface of the vibration part and a second surface of the vibration part opposite to the first surface, and a signal supply member electrically connected to the vibration part and connected to the driving circuit part.

According to one or more embodiments of the present disclosure, a portion of the signal supply member may be accommodated between the cover member and the vibration part.

According to one or more embodiments of the present disclosure, the sound apparatus further may comprise a vibration member, and a supporting member having an internal space and supporting the vibration member. The vibration apparatus of the sound apparatus may be in the internal space of the supporting member and is disposed to vibrate the vibration member.

According to one or more embodiments of the present disclosure, the vehicle body bottom may comprise an accommodation part configured to accommodate the one or more virtual engine sound apparatuses. The supporting member of the sound apparatus may be accommodated into the accommodation part. The sound apparatus may output a virtual engine sound toward an earth-surface direction.

A sound apparatus according to an embodiment of the present disclosure may be applied to or included in a sound generating apparatus disposed at an apparatus or a display apparatus. The apparatus or the display apparatus according to an embodiment of the present disclosure may be applied to or included in mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theatre apparatuses, theatre display apparatuses, TVs, wall paper display apparatuses, signage apparatuses, game machines, notebook computers, monitors, cameras, camcorders, and home appliances, or the like. Further, the sound apparatus according to one or more embodiments of the present disclosure may be applied to or included in an organic light-emitting lighting apparatus or an inorganic light-emitting lighting apparatus. When the sound apparatus is applied to or included in the lighting apparatuses, the lighting apparatuses may act as lighting and a speaker. In addition, when the sound apparatus according to one or more embodiments of the present disclosure is applied to or included in the mobile apparatuses, or the like, the sound apparatus may be one or more of a speaker, a receiver, and a haptic device, but embodiments of the present disclosure are not limited thereto.

It will be apparent to those skilled in the art that various modifications and variations can be made in the sound driving circuit, the sound apparatus including the same, and the vehicular apparatus including the sound apparatus of the present disclosure without departing from the technical idea or scope of the disclosure. Thus, it is intended that the present disclosure cover the modifications and variations of this disclosure provided they come within the scope of the appended claims and their equivalents.

What is claimed is:

1. A sound driving circuit, comprising:
an audio processor generating an input audio signal based on a sound source;
a signal conversion circuit converting the input audio signal into a piezoelectric audio signal; and
an amplifier circuit amplifying the piezoelectric audio signal to generate a piezoelectric driving signal for driving a vibration apparatus of a piezoelectric-type.

2. The sound driving circuit of claim 1, wherein the signal conversion circuit comprises a filter circuit attenuating a high-pitched sound band signal of the input audio signal to generate the piezoelectric driving signal.

3. The sound driving circuit of claim 2, wherein the high-pitched sound band signal has a frequency of 1 kHz or more.

4. The sound driving circuit of claim 2,
wherein the signal conversion circuit further comprises:
a correction circuit increasing a first pitched sound band signal of the input audio signal and/or decreasing a second pitched sound band signal differing from the first pitched sound band signal to generate a first audio correction signal;
a level control circuit controlling a volume level of the first audio correction signal to generate a second audio correction signal; and
a clipping circuit removing noise of the second audio correction signal to generate a third audio correction signal, and
wherein the filter circuit attenuates the high-pitched sound band signal of the third audio correction signal to generate the piezoelectric driving signal.

5. The sound driving circuit of claim 4,
wherein the first pitched sound band signal has a frequency of 250 Hz to 600 Hz, and
wherein the second pitched sound band signal has a frequency of 1 kHz or more.

6. The sound driving circuit of claim 4,
wherein the correction circuit includes a first correction circuit for increasing the first pitched sound band signal, a second correction circuit for decreasing the second pitched sound band signal, and a mixing circuit for mixing the increased first pitched sound band signal and the decreased second pitched sound band signal to generate the first audio correction signal.

7. A sound driving circuit, comprising:
an audio processor generating an audio signal based on a sound source;
a preamplifier circuit amplifying the audio signal to generate an input audio signal;
a signal conversion circuit converting the input audio signal into a piezoelectric audio signal; and
an amplifier circuit amplifying the piezoelectric audio signal to generate a piezoelectric driving signal for driving a vibration apparatus of a piezoelectric-type.

8. The sound driving circuit of claim 7, wherein the signal conversion circuit comprises a filter circuit attenuating a high-pitched sound band signal of the input audio signal to generate the piezoelectric driving signal.

9. The sound driving circuit of claim 8, wherein the high-pitched sound band signal has a frequency of 1 kHz or more.

10. The sound driving circuit of claim 8,
wherein the signal conversion circuit further comprises:
a correction circuit increasing a first pitched sound band signal of the input audio signal and/or decreasing a second pitched sound band signal differing from the first pitched sound band signal to generate a first audio correction signal;
a level control circuit controlling a volume level of the first audio correction signal to generate a second audio correction signal; and
a clipping circuit removing noise of the second audio correction signal to generate a third audio correction signal, and
wherein the filter circuit attenuates the high-pitched sound band signal of the third audio correction signal to generate the piezoelectric driving signal.

11. The sound driving circuit of claim 10,
wherein the first pitched sound band signal has a frequency of 250 Hz to 600 Hz, and
wherein the second pitched sound band signal has a frequency of 1 kHz or more.

12. The sound driving circuit of claim 10,
wherein the correction circuit includes a first correction circuit for increasing the first pitched sound band signal, a second correction circuit for decreasing the second pitched sound band signal, and a mixing circuit for mixing the increased first pitched sound band signal and the decreased second pitched sound band signal to generate the first audio correction signal.

13. A sound driving circuit, comprising:
an audio processor generating a first input audio signal and one or more second input audio signals based on a sound source;
a signal conversion circuit converting the first input audio signal into a piezoelectric audio signal; and
an amplifier circuit amplifying the one or more second input audio signals to generate one or more actuator driving signals for driving one or more actuators of a coil-type and amplifying the piezoelectric audio signal to generate a piezoelectric driving signal for driving a vibration apparatus of a piezoelectric-type.

14. The sound driving circuit of claim 13, wherein the signal conversion circuit comprises a filter circuit attenuating a high-pitched sound band signal of the first input audio signal to generate the piezoelectric driving signal.

15. The sound driving circuit of claim 14, wherein the high-pitched sound band signal has a frequency of 1 kHz or more.

16. The sound driving circuit of claim 14,
wherein the signal conversion circuit further comprises:
a correction circuit increasing a first pitched sound band signal of the first input audio signal and/or decreasing a second pitched sound band signal differing from the first pitched sound band signal to generate a first audio correction signal;
a level control circuit controlling a volume level of the first audio correction signal to generate a second audio correction signal; and
a clipping circuit removing noise of the second audio correction signal to generate a third audio correction signal, and
wherein the filter circuit attenuates the high-pitched sound band signal of the third audio correction signal to generate the piezoelectric driving signal.

17. The sound driving circuit of claim 16,
wherein the first pitched sound band signal has a frequency of 250 Hz to 600 Hz, and
wherein the second pitched sound band signal has a frequency of 1 kHz or more.

18. The sound driving circuit of claim 16,
wherein the correction circuit includes a first correction circuit for increasing the first pitched sound band signal, a second correction circuit for decreasing the second pitched sound band signal, and a mixing circuit for mixing the increased first pitched sound band signal and the decreased second pitched sound band signal to generate the first audio correction signal.

19. A sound driving circuit, comprising:
an audio processor generating a first audio signal and one or more second input audio input signals based on a sound source;
a preamplifier circuit amplifying the one or more second audio signals to generate the one or more second input audio signals and amplifying the first audio signal to generate the first input audio signal;
a signal conversion circuit converting the first input audio signal into a piezoelectric audio signal; and
an amplifier circuit amplifying the one or more second input audio signals to generate one or more actuator driving signals for driving one or more actuators of a coil-type and amplifying the piezoelectric audio signal to generate a piezoelectric driving signal for driving a vibration apparatus of a piezoelectric-type.

20. The sound driving circuit of claim 19, wherein the signal conversion circuit comprises a filter circuit attenuating a high-pitched sound band signal of the first input audio signal to generate the piezoelectric driving signal.

21. The sound driving circuit of claim 20, wherein the high-pitched sound band signal has a frequency of 1 kHz or more.

22. The sound driving circuit of claim 20,
wherein the signal conversion circuit further comprises:
a correction circuit increasing a first pitched sound band signal of the first input audio signal and/or decreasing a second pitched sound band signal differing from the first pitched sound band signal to generate a first audio correction signal;
a level control circuit controlling a volume level of the first audio correction signal to generate a second audio correction signal; and
a clipping circuit removing noise of the second audio correction signal to generate a third audio correction signal, and
wherein the filter circuit attenuates the high-pitched sound band signal of the third audio correction signal to generate the piezoelectric driving signal.

23. The sound driving circuit of claim 22,
wherein the first pitched sound band signal has a frequency of 250 Hz to 600 Hz, and
wherein the second pitched sound band signal has a frequency of 1 kHz or more.

24. The sound driving circuit of claim 22,
wherein the correction circuit includes a first correction circuit for increasing the first pitched sound band signal, a second correction circuit for decreasing the second pitched sound band signal, and a mixing circuit for mixing the increased first pitched sound band signal and the decreased second pitched sound band signal to generate the first audio correction signal.

25. A sound apparatus, comprising:
a vibration apparatus including a piezoelectric material; and
a driving circuit part connected to the vibration apparatus,
wherein the driving circuit part comprises the sound driving circuit of claim 1, and
wherein the sound driving circuit applies the piezoelectric driving signal to the vibration apparatus.

26. The sound apparatus of claim 25, wherein the vibration apparatus comprises:
a vibration part including the piezoelectric material;
a cover member covering at least one or more of a first surface of the vibration part and a second surface of the vibration part opposite to the first surface; and
a signal supply member electrically connected to the vibration part and connected to the driving circuit part.

27. The sound apparatus of claim 25, further comprising a passive vibration member,
wherein the vibration apparatus is disposed to vibrate the passive vibration member.

28. The sound apparatus of claim 27, wherein the passive vibration member comprises any one of a display panel including a pixel configured to display an image, a screen panel on which an image is to be projected from a display apparatus, a lighting panel, a signage panel, a vehicular interior material, a vehicular exterior material, a vehicular glass window, a vehicular seat interior material, a vehicular ceiling material, a building ceiling material, a building interior material, a building glass window, an aircraft interior material, an aircraft glass window, and a mirror.

29. The sound apparatus of claim 25, further comprising:
a vibration member; and
a supporting member having an internal space and configured at a periphery of the vibration member,
wherein the vibration apparatus is in the internal space of the supporting member and is disposed to vibrate the vibration member.

30. A sound apparatus, comprising:
a vibration apparatus including a piezoelectric material;
one or more actuators including a magnet and a coil; and
a driving circuit part connected to the vibration apparatus and the one or more actuators,
wherein the driving circuit part comprises the sound driving circuit of claim 13, and
wherein the sound driving circuit applies the piezoelectric driving signal to the vibration apparatus and applies the one or more actuator driving signals to the one or more actuators.

31. The sound apparatus of claim 30, wherein the vibration apparatus comprises:
a vibration part including the piezoelectric material;
a cover member covering at least one or more of a first surface of the vibration part and a second surface of the vibration part opposite to the first surface; and
a signal supply member electrically connected to the vibration part and connected to the driving circuit part.

32. A vehicular apparatus, comprising:
an exterior material;
an interior material covering the exterior material; and
one or more sound generating apparatuses configured to output a sound in one or more of the exterior material, the interior material, and a region between the exterior material and the interior material,
wherein the one or more sound generating apparatuses comprise the sound apparatus of claim 25.

33. The vehicular apparatus of claim 32, further comprising:
a vibration member; and
a supporting member having an internal space and supporting the vibration member,
wherein the vibration apparatus of the sound apparatus is in the internal space of the supporting member and is disposed to vibrate the vibration member.

34. The vehicular apparatus of claim 32, wherein the vibration apparatus of the sound apparatus comprises:
a vibration part including the piezoelectric material;
a cover member covering at least one or more of a first surface of the vibration part and a second surface of the vibration part opposite to the first surface; and
a signal supply member electrically connected to the vibration part and connected to the driving circuit part.

35. The vehicular apparatus of claim 34, wherein a portion of the signal supply member is accommodated between the cover member and the vibration part.

36. The vehicular apparatus of claim 32, wherein the interior material comprises at least one or more of a dash board, a pillar interior material, a roof interior material, a door interior material, a seat interior material, a handle interior material, a floor interior material, and a rear package interior material.

37. The vehicular apparatus of claim 32, wherein the exterior material comprises at least one or more of a hood panel, a front fender panel, a door panel, a roof panel, a pillar panel, a trunk panel, a front bumper, a rear bumper, a spoiler, a headlight, a taillight, a fog light, and a vehicle body bottom.

38. A vehicular apparatus, comprising:
an exterior material;
an interior material covering the exterior material; and
one or more sound generating apparatuses configured to output a sound in one or more of the exterior material, the interior material, and a region between the exterior material and the interior material,
wherein the one or more sound generating apparatuses comprise the sound apparatus of claim 30.

39. The vehicular apparatus of claim 38, wherein the vibration apparatus of the sound apparatus comprises:
a vibration part including the piezoelectric material;
a cover member covering at least one or more of a first surface of the vibration part and a second surface of the vibration part opposite to the first surface; and
a signal supply member electrically connected to the vibration part and connected to the driving circuit part.

40. The vehicular apparatus of claim 39, wherein a portion of the signal supply member is accommodated between the cover member and the vibration part.

41. The vehicular apparatus of claim 38, wherein the interior material comprises at least one or more of a dash board, a pillar interior material, a roof interior material, a door interior material, a seat interior material, a handle interior material, a floor interior material, and a rear package interior material.

42. The vehicular apparatus of claim 38, wherein the exterior material comprises at least one or more of a hood panel, a front fender panel, a door panel, a roof panel, a pillar panel, a trunk panel, a front bumper, a rear bumper, a spoiler, a headlight, a taillight, a fog light, and a vehicle body bottom.

43. The vehicular apparatus of claim 38, wherein the one or more actuators of the sound apparatus are disposed at one or more of a dash board, a door frame, a rear package interior material, a pillar interior material, a roof interior material, a door interior material, a seat interior material, a handle interior material, and a floor interior material.

44. A vehicular apparatus, comprising:
a vehicle body bottom frame; and
a vehicle body bottom covering the vehicle body bottom frame; and
one or more virtual engine sound apparatuses mounted on the vehicle body bottom or a region between the vehicle body bottom frame and the vehicle body bottom,
wherein the one or more virtual engine sound apparatuses comprise the sound apparatus of claim 25.

45. The vehicular apparatus of claim 44, wherein the one or more virtual engine sound apparatuses are disposed to correspond to a center of the vehicle body bottom.

46. The vehicular apparatus of claim 44, wherein the vibration apparatus of the sound apparatus comprises:
a vibration part including the piezoelectric material;
a cover member covering at least one or more of a first surface of the vibration part and a second surface of the vibration part opposite to the first surface; and
a signal supply member electrically connected to the vibration part and connected to the driving circuit part.

47. The vehicular apparatus of claim 46, wherein a portion of the signal supply member is accommodated between the cover member and the vibration part.

48. The vehicular apparatus of claim 44, wherein the sound apparatus further comprises:
a vibration member; and
a supporting member having an internal space and supporting the vibration member,
wherein the vibration apparatus of the sound apparatus is in the internal space of the supporting member and is disposed to vibrate the vibration member.

49. The vehicular apparatus of claim 48,
wherein the vehicle body bottom comprises an accommodation part configured to accommodate the one or more virtual engine sound apparatuses,
wherein the supporting member of the sound apparatus is accommodated into the accommodation part, and
wherein the sound apparatus outputs a virtual engine sound toward an earth-surface direction.
